(19) United States
(12) Patent Application Publication
(10) Pub. No.: US 2024/0126957 A1
(43) Pub. Date: Apr. 18, 2024

(54) WELL REACTOR SYSTEMS AND METHODS FOR BIOMASS CONVERSION AND COMPUTER-READABLE MEDIA

(71) Applicant: ENOVERRA ENERGY & ENVIRONMENT INC, HOUSTON, TX (US)

(72) Inventor: MUKESH KAPILA, HOUSTON, TX (US)

(73) Assignee: ENOVERRA ENERGY & ENVIRONMENT INC, HOUSTON, TX (US)

(21) Appl. No.: 18/483,966

(22) Filed: Oct. 10, 2023

Related U.S. Application Data
(60) Provisional application No. 63/379,130, filed on Oct. 11, 2022.
(60) Provisional application No. 63/581,486, filed on Sep. 8, 2023.

(51) Int. Cl. G06F 30/28

(52) U.S. Cl. CPC G06F 30/28

(57) ABSTRACT

Methods of modeling methods of producing biocrude oil and other products from biomass using hydrothermal liquefaction (HTL) performed in a well reactor or producing hydrochar from biomass using hydrothermal carbonization (HTC) performed in a well reactor. Casing and tubing positioned in the well reactor form an annulus. The casing and tubing define an HTL or HTC reaction zone in a bottom portion of the well and a heat transfer and separation zone above the reaction zone. The well includes a cable having an electric heating element positioned in the tubing in the reaction zone. The well depth and the electrical heating element are sized to produce temperature and pressure in the reaction zone sufficient to form sub-critical water and produce a product fluid comprising the biocrude oil via HTL or hydrochar via HTC. Computer-readable media encoding the methods of modeling.

### CROSS-REFERENCE TO RELATED APPLICATIONS

This application claims domestic priority benefit under 35 U.S.C. § 119(e) from Applicant's provisional patent application No. 63/379,130, filed Oct. 11, 2022, and Applicant's provisional patent application No. 63/581,486, filed Sep. 8, 2023. This application is also related to Applicant's application Nos. 63/379,127 and 63/379,129, both filed Oct. 11, 2022. All of these patent applications are hereby explicitly incorporated herein by reference.

### BACKGROUND INFORMATION

### Technical Field

The present disclosure relates in general to modeling systems and methods useful in converting biomass into useful products, for example, the production of biocrude, and the production of hydrochar. Biocrude is a liquid fuel like petroleum crude that can be upgraded to the whole distillate range of petroleum derived fuel products. Hydrochar is a paste or powder that can be used as a soil amendment simultaneously sequestering carbon, as a carbon neutral fuel similar to lignite, in concrete to add strength and sequester carbon, as a coke alternative, and in other end uses. In particular, the present disclosure relates to modeling of systems and methods employing hydrothermal conditions, for example in certain embodiments hydrothermal liquefaction (HTL), and in other embodiments hydrothermal carbonization (HTC), for production of useful products, such as biocrude using HTL and hydrochar using HTC, methods of evaluating such systems and methods, methods of comparing such systems and methods, methods of simulating such systems and methods, and to computer readable media encoding one or more of such methods.

### Background Art

HTL requires very high pressures and temperatures, about 3,000 psi and 300° C. These temperatures and pressures are a very challenging operating conditions particularly under continuous processing conditions, typically requiring specialized pumps, depressurizing valves and pressure recovery, heat exchangers that are not commercially available, exotic metallurgy and atypical wall thicknesses. In addition, there are numerous issues related to excessive wear and tear, safety, redundancy requirements and very high costs. In particular, the high thermal energy required to heat feed biomass slurry to the desired temperature must be recovered for economic viability, thereby requiring heat exchangers capable of operating at the target temperatures and pressures which are not commercially available for the relatively high processing rates.

Historically, treating biomass to achieve one or more usable end products and sequester carbon has focused on several “dry” processes, that is, processes requiring dry biomass feedstock, such as pyrolysis, gasification, and incineration. All of these require drying the biomass feedstock, requiring energy input to drive off most of the moisture.

At this time, globally, there are no commercial scale HTL or HTC operations for converting biomass to biocrude or hydrochar, respectively, largely due to these challenges. While use of HTL to produce biocrude and HTC to produce biochar have increased, there remains a need for improved HTL systems and methods for production of biocrude from biomass, improved HTC systems and methods for production of hydrochar from biomass, methods of evaluating such systems and methods, methods of comparing such systems and methods, methods of simulating such systems and methods, and to computer readable media encoding one or more of such methods.

### SUMMARY

In accordance with the present disclosure, methods of modeling HTL systems and methods for production of biocrude from biomass, methods of modeling HTC systems and methods for production of hydrochar from biomass, methods of evaluating such systems and methods, methods of comparing such systems and methods, methods of simulating such systems and methods, and computer readable media encoding one or more of such methods are described which reduce or overcome many of the faults of previously known HTL systems and methods. Applicant's co-pending '127, '129, '130, and '486 applications describe converting biomass at high volumetric flow rates into biocrude using HTL or hydrochar using HTC. The biomass is prepared to generate a biomass slurry for HTL or HTC processing.

A first aspect of this disclosure are methods of modeling of a hydrothermal system, the methods comprising:
a) selecting flow rate, physical properties, and chemical properties of a biomass slurry precursor composition and one or more chemical additives to be mixed therewith;
b) selecting operating parameters of solids attrition and mixing equipment;
c) modeling formation of a biomass slurry using data input from steps (a) and (b);
d) modeling a well reactor and hydrothermal reactions, the well reactor comprising:
   1) one or more tubing positioned inside a casing of a well in a subterranean formation, the well having a well depth, a well top positioned at a surface location, and a bottom portion positioned at a subterranean location, the casing and the one or more tubing positioned therein forming an annulus there between;
   2) the casing and the one or more tubing defining an HTL or HTC reaction zone in the bottom portion of the well and a heat transfer and separation zone above the HTL or HTC reaction zone;
   3) one or more cables each comprising an electric heating element positioned in respective one or more of the one or more tubing, the heating element positioned in the HTL or HTC reaction zone;
e) modeling the biomass slurry continuously flowing into the top of the well at a first temperature and a first pressure, and flowing downward through at least one of the one or more tubing, to form a continuously flowing biomass slurry stream;
f) modeling heating of the continuously flowing biomass slurry stream in the HTL or HTC reaction zone employing the electrical heating element;
g) modeling a multiphase, continuously flowing product fluid stream in the HTL or HTC reaction zone, the well depth and the electrical heating element configured to produce a second temperature and a second pressure in the HTL or HTC reaction zone sufficient to form sub-critical water but insufficient to form supercritical water, the multiphase, continuously flowing fluid product stream flowing upward through the annulus and thermally interacting with the continuously flowing biomass slurry stream flowing downward through the one or more tubing;
h) modeling heat transfer between the multiphase, continuously flowing product fluid stream, the well, and the formation, and optionally through the casing and casing construction materials, using a first equation;
i) modeling heat transfer between the multiphase, continuously flowing product fluid stream and the continuously flowing biomass slurry using a second equation;
j) modeling heat transfer between the heating element and the continuously flowing biomass slurry using a third equation, wherein the first equation, the second equation, and the third equation form a coupled system of equations; and
k) performing a mass and energy balance for the well reactor and the subterranean formation by solving the coupled system of equations numerically, providing heat transfer rates to determine the pressure, temperature and quality profile in the continuously flowing product fluid stream.

Note that in embodiments where the reaction zone is an HTL reaction zone, the multiphase, continuously flowing product fluid stream is a fluid stream comprising biocrude oil produced by converting at least a portion of the continuously flowing biomass slurry stream into the biocrude oil by HTL. In embodiments where the reaction zone is an HTC reaction zone, the multiphase, continuously flowing product fluid stream comprises amorphous solid hydrochar produced by converting at least a portion of the continuously flowing biomass slurry stream into the hydrochar by HTC.

A second aspect of this disclosure are computer-readable media encoding one or more methods of the first aspect of this disclosure.

A third aspect of this disclosure are methods of modeling of a hydrothermal system, the methods comprising:
a) selecting a geothermal temperature model of a formation as a function of depth;
b) selecting lithology and thermal conductivity of the formation;
c) selecting a wellbore construction 3D geometric model, the wellbore construction 3D model comprising:
   1) one or more tubing positioned inside a casing in a subterranean formation, a well depth, a well top positioned at a surface location, and a bottom portion positioned at a subterranean location, the casing and the one or more tubing positioned therein forming an annulus there between;
   2) the casing and the one or more tubing defining an HTL or HTC reaction zone in the bottom portion of the well and a heat transfer and separation zone above the HTL or HTC reaction zone; and
   3) one or more cables each comprising an electric heating element positioned in respective one or more of the one or more tubing, the heating element positioned in the HTL or HTC reaction zone;
d) forming a formation subsurface segmentation profile using steps (a)-(c) and calculating an overall heat transfer coefficient between the wellbore construction 3D model and the formation;
e) selecting boundary conditions at a casing/formation interface;
f) inputting biomass slurry composition and heat input from an electrical heating element positioned in the HTL or HTC reaction zone in the wellbore to produce a value of total heat that would be generated in the wellbore from hydrothermal reactions in the wellbore;
g) modeling a steady state conduction heat flow at the casing/formation interface using the overall heat transfer coefficient, the boundary conditions, and the value of total heat generated in the wellbore from the hydrothermal reactions in the wellbore; and
h) modeling at least one of:
   1) a formation 3D temperature distribution model at a time t;
   2) a formation 3D heat loss rate at a distance d from the wellbore; and
   3) a formation heat flux at the time t and the distance d.

A fourth aspect of this disclosure are computer-readable media encoding one or more methods of the third aspect of this disclosure.

These and other features of the systems and methods of the disclosure will become more apparent upon review of the brief description of the drawings, the detailed description, and the claims that follow. Wherever the term “comprising” is used herein, other embodiments where the term “comprising” is substituted with “consisting essentially of” are explicitly disclosed herein. Wherever the term “comprising” is used herein, other embodiments where the term “comprising” is substituted with “consisting of” are explicitly disclosed herein. Moreover, the use of negative limitations is specifically contemplated; for example, certain systems and methods may comprise several physical components and features but may be devoid of certain optional hardware and/or other features. For example, certain systems and methods may be devoid of submersible pumps. As another example, systems and methods of this disclosure may be devoid of heat exchangers employing inert metals, or other expensive equipment. In yet another example, systems and methods of the present disclosure may be devoid of any unit or component that would introduce an oxidizing chemical into the biomass slurry.

### BRIEF DESCRIPTION OF THE DRAWINGS

The manner in which the objectives of this disclosure and other desirable characteristics can be obtained is explained in the following description and attached drawings in which:

FIG. 1 schematically illustrates a logic diagram for modeling steady state mass flow simulation of a well reactor and surface separation method and system in accordance with one embodiment of the present disclosure;

FIGS. 2 and 3 are schematic illustrations of a wellbore reactor, with FIG. 2 illustrating steady state heat generation and heat transfer within one design of a well reactor, and FIG. 3 illustrating transient heat transfer outside the wellbore reactor and to the formation;

FIG. 4 schematically illustrates a logic diagram for modeling steady state heat generation and heat transfer for a well reactor in accordance with another embodiment of the present disclosure;

FIG. 5 schematically illustrates a logic diagram of one thermal model solver useful in certain embodiments of the present disclosure;

FIG. 6 illustrates schematically subsurface segmentation for preparing models in accordance with the present disclosure;

FIG. 7 schematically illustrates typical elements offering resistance to heat losses from the well reactors in methods being modeled in accordance with this disclosure;

FIG. 8 is a logic diagram for modeling transient heat transfer of a well reactor and method in accordance with another embodiment of the present disclosure;

FIGS. 9, 10, 19A and 19B schematically illustrate various system and method embodiments in accordance with the present disclosure;

FIGS. 11, 12, 13, 14, 15A, 15B, 16, 17A, 17B, and 17C are various schematic illustrations and graphical representations of modeling of heat transfer in well reactors in accordance with the present disclosure; and

FIG. 18 is a graphical representation of pressure and temperatures in HTL systems and methods in accordance with the present disclosure, specifically pressure and temperature combinations to avoid hydrothermal carbonization and promote HTL.

It is to be noted, however, that the appended drawings are not to scale and illustrate only typical embodiments of this disclosure, and are therefore not to be considered limiting of its scope, for the disclosure may admit to other equally effective embodiments. Identical reference numerals are used throughout the several views for like or similar elements.

### DETAILED DESCRIPTION

In the following description, numerous details are set forth to provide an understanding of the disclosed methods, systems, and apparatus. However, it will be understood by those skilled in the art that the methods, systems, and apparatus may be practiced without these details and that numerous variations or modifications from the described embodiments may be possible. All U.S. published patent applications, U.S. Patents, and non-patent literature referenced herein are hereby explicitly incorporated herein by reference. In the event definitions of terms in the referenced patents and applications conflict with how those terms are defined in the present application, the definitions for those terms that are provided in the present application shall be deemed controlling. Where a range of values describes a parameter, all sub-ranges, point values and endpoints within that range are explicitly disclosed herein. This document follows the well-established principle that the words “a” and “an” mean “one or more” unless we evince a clear intent to limit “a” or “an” to “one.” For example, when we state “flowing a biomass slurry into a top of a tubing positioned inside a casing of a well”, we mean that the specification supports a legal construction of “a tubing” that encompasses structure distributed among multiple physical structures, and a legal construction of “a well” that encompasses structure distributed among multiple physical structures.

The World Commission on Environment and Development defined sustainable development as development that meets the needs of the present without compromising the ability of future generations to meet their own needs. With the growing awareness on the need to mitigate greenhouse gas (GHG) emissions and the inevitable depletion of fossil fuel, the world is on the journey of transitioning towards more sustainable and renewable alternatives. The need to minimize fossil fuel use and mitigate its associated GHG emissions drives the ongoing growth in sustainable and renewable alternative energy. In the world's consumption of fossil fuel (coal, natural gas, and oil), 91% is used for energy applications. In crude oil consumption, 63% is for the global transportation sector and 16% is used to make building-block chemicals and polymers. With transportation demand increasing globally, driven in part by population growth, the challenge to decrease the world's reliance on fossil fuels requires the implementation of cost-effective, large-scale, renewable energy-based transport fuel projects. Ong et al., “A Kraft Mill-Integrated Hydrothermal Liquefaction Process for Liquid Fuel Co-Production”, pp. 1-23, Processes 2020, 8, 1216 (2020), MDPI, Basel, Switzerland (hereafter Ong et al.).

Bioenergy is a renewable energy that uses biomass to produce energy. Biomass can be sewage sludge, manure, municipal solid waste, agriculture, forest residues, energy crops and others. The major concerns of bioenergy are biomass availability, sustainability issues and competition between the alternative uses of biomass (for instance, competition for feed and food). Hence, the use of waste streams may contribute to an improvement of bioenergy production. Moreover, the use of waste for production of energy contributes to a circular economy that, in turn, is a global plan for reduction of waste generation and reduction of the use of resources. Moura, T. C. P., “Modelling of Wet Air Oxidation in a Deep Well Reactor for Biomass Treatment”, Master dissertation (October 2021), available from À Faculdade De Engenharia Da Universidade Do Porto Em Chemical Engineering (hereafter “Moura”).

The estimated annual global volume of biomass (as of 2020) is as presented in Table 1, where biocrude volumes are based on 40% conversion of biomass (dry wt. %):

TABLE 1
Estimated Annual Global Volume of Biomass (as of 2020)

| | Biomass | Potential | Potential CO₂ |
|---|---|---|---|
| Global Summary | Million | Biocrude | Reduction |
| (Annual) | tons (dry) | Million bbl. | Million tons/yr. |
| Wastewater | 57 | 143 | 62 |
| Treatment Sludge | | | |
| Livestock Manure | 15 | 38 | 16 |
| Agricultural | 4,312 | 10,848 | 4,665 |
| Residues | | | |
| Municipal & | 523 | 1,317 | 566 |
| Industrial Waste | | | |
| Other | 100 | 252 | 108 |
| Total Global | 5,007 | 12,597 | 5,417 |

### Hydrothermal Liquefaction Technology

Our co-pending applications, mentioned herein and incorporated by reference herein in their entirety, describe several system and method embodiments for converting biomass to biocrude oil and other useful products. Prior to the systems and methods of the present disclosure and the disclosures in our co-pending applications, the HTL_process has been shown to be difficult to scale up. Most of the research into HTL has been done in the laboratory setting in small scale reactors. This means that the process conditions and costs are estimated but not implicitly known. The pressures and temperatures needed will greatly increase the cost of large-scale equipment. Bailey, et al., “Hydrothermal Liquefaction of Food Waste, A Major Qualifying Project Report”, submitted to the faculty of Worcester Polytechnic Institute, Apr. 26, 2018 (hereinafter Bailey et al.).

In a typical HTL process, approximately 16 percent (dry ash free wt. percent) of the feedstock is converted into HTL off-gas stream consisting of CO₂, CH₄, CO and H₂, primarily composed of 92 percent CO₂ and 8 percent C₁-C5 gases. “Conceptual Biorefinery Design and Research Targeted for 2022: Hydrothermal Liquefaction Processing of Wet Waste to Fuels”, December 2017, Prepared for the U.S. Department of Energy under Contract DE-AC05-76RL01830 by Pacific Northwest National Laboratory. CO₂ and hydrocarbon gases can be separated using well established methods such as amine solution extraction and pressure swing adsorption allowing for the recovery of hydrocarbon gases to supplement fuel consumption in the general process or electricity production.

Some feedstock is converted into solid elemental carbon char from hydrothermal carbonization (HTC) which is a thermochemical conversion process that uses heat to convert wet biomass feedstocks to hydrochar. HTC occurs at temperatures ranging from about 180° C. to about 250° C., under autogenous (automatically generated) pressure, with feedstock residence time ranging from about 0.5 to 8 hours. Ahmad, F., et al., “Hydrothermal processing of biomass for anaerobic digestion—A review”, Renewable and Sustainable Energy Reviews, 98, 108-124 (2018); Khan, T. A., et al., “Hydrothermal carbonization of lignocellulosic biomass for carbon rich material preparation: A review, Biomass and Bioenergy, 130, 105384 (2019). This solid carbon cannot revert to carbon dioxide or methane and subsequently be released to the atmosphere. When used as a soil amendment, the carbon is permanently removed from the atmosphere. The use of hydrochar can improve soil quality by enhancing its water and nutrient retention properties. Zhang, Z., et al., “Insights into biochar and hydrochar production and applications: a review”, Energy, 171, 581-598 (2019). However, the char may contain toxic compounds which could limit its use as soil amendment. Sivaprasad, S. et al., “Hydrothermal Carbonization: Upgrading Waste Biomass to Char”, Department of Food, Agricultural and Biological Engineering, The Ohio State University, downloaded from url: https://ohiolines)su,edu/factsheet/fabe-6622. Hence the converted biomass into liquid and solid products is carbon negative or in other words, carbon is removed from the atmosphere. While there are benefits of HTC, it reduces HTL biocrude yields. If the objective is to maximize biocrude yields as is the case for the systems and methods of the present disclosure, then the feed slurry should remain in the temperature range of about 180° C. to about 250° C. environment for as short a time as possible.

As explained in our co-pending applications, the critical point of water is at 374° C. and 22.1 MPa (221 bar). Liquid water, below the critical point, is referred to as subcritical water and above as supercritical water. According to the systems and methods of the present disclosure, the treatment of biomass is carried out in subcritical water, at which water is still in a liquid phase and acts as a non-polar solvent enhancing the solubility of organic compounds of biomass. Water at subcritical conditions has a much lower dielectric constant and higher ion product than water at normal conditions and therefore provides a reaction medium with improved solvent and catalytic properties. While HTL chemistry is complicated, the general reaction pathways can be put into three basic categories: depolymerization of the biomass components; decomposition of biomass monomers by cleavage, dehydration, decarboxylation, and deamination; and recombination of reactive fragments. The biocrude from sludge is similar to biocrude from algae HTL and comprises a mixture of fatty acids, amides, ketones, hydrocarbons, phenols, alcohols and other components. Furthermore, long residence times have shown a decrease in the viscosity of the biocrude. A generalized reaction pathway of HTL processes is illustrated in Rudra, et al., “Hydrothermal liquefaction of biomass for biofuel production”, Department of Engineering Science, Faculty of Engineering and Sciences, University of Agder, Norway, April 2021.

### Biomass to Biocrude

Liquid biocrude is the key product of HTL systems and methods of the present disclosure. With an upgrading process, this biocrude can be transformed to the whole distillate range of petroleum-derived equivalent fuel products. When compared to gasification, pyrolysis and HTL have a simpler technical conversion of biomass to a liquid fuel. However, when compared to pyrolysis oils, the lower oxygen content in HTL biocrude makes it less corrosive and provides it with higher heating value. Conventional (fossil fuel-derived) petroleum that has a calorific content of 43-46 MJ/kg compared with 30-36 MJ/kg for HTL bio-crude, and 15-22 MJ/kg for pyrolysis oils.

The main pathway that produces biocrude in systems and methods of the present disclosure is through the reduction of oxygen and other oxidizing compositions in the biomass feed. Oxygen accounts for about 40-60 percent of the dry weight of biomass. This is done in systems and methods of the present disclosure by reducing the number of oxygen molecules bound to the organics and increasing the organic molecules size. The reduction of bound oxygen reduces the solubility of the organic compound by making it less polar and more hydrophobic. This reduction in oxygen increases the energy density of the resulting biocrude. Two major chemical reactions (Lange, J-P., “Lignocellulose Liquefaction to Biocrude: A Tutorial Review”, hemSusChem (2018), 11, 997 -1014) taking place are alkylation of phenolic compounds and the ketonization of carboxylic acids. Removing oxygen in these ways is ideal for systems and methods of the present disclosure as it either removes it as water, increasing the total carbon yield, or as carbon dioxide which increases the hydrogen to carbon ratio of the final products. Biocrude products of the HTL systems and methods of the present disclosure on average are less than 1 percent oxygen. The addition of catalysts have been shown to improve the percent conversion from the aqueous to oil phase.

### Wet Biomass Feedstocks—Properties and Preparation for Processing (Elliott et al.)

Table 2 presents some common feedstock utilized in HTL systems and methods of the present disclosure. Table 2 also presents a summary of the HTL results published on the respective feedstock to date. It can be seen that the wet manure and sewage sludge feedstock have not been processed in continuous systems, although results from batch systems are promising for their application in continuous systems. A further advantage of using hydrothermal processing for sludges and manures is the effect of sterilizing bioactive contaminants.

TABLE 2
Summary of HTL feedstock and continuous-flow reactor results (Elliott et al.)

| Feedstock | | | | | |
|---|---|---|---|---|---|
| (dry basis) | Lignocellulosics | Macroalgae | Microalgae | Manures | Sewer Sludge |
| Ash | 3-8 | 15-35 | 7-26 | 10-20 | 20-50 |
| H/C | 1.2 | 1.2 | 1.6 | 1.5 | 1.6 |
| O % | 35-45 | 25-40 | 25-30 | 35-45 | 50 |
| N % | 0.5-3 | 3-7 | 5-9 | 3-6 | 3-8 |
| HHV, MJ/kg | 12-20 | 10-20 | 25-30 | 10-20 | 14 |
| Size (mm) | 1-100 | 1-10 | 1-100 | 1-10 | 1-100 |
| Feed | Yes | Not all strains | No | No | Depending on |
| Formatting | | | | | source |
| Required | | | | | |
| Reference | Umeki et | Ross et al | Biller and | Vardon et al. | Fonts et al. |
| | al.(2010); | (2008) | Ross (2011) | (2011); Wang | (2012) |
| | Wang et al | | | et al. (2011) | |
| | (2011) | | | | |
| Biocrude | | | Continuous | | |
| | | | HTL Results | | |
| Yield, % daf* | 35 | 27 | 38-64 | — | — |
| Energy | 64 | 52 | 60-78 | — | — |
| Recovery % | | | | | |
| N % | 0.3 | 3-4 | 4-8 | — | — |
| O % | 12 | 6-8 | 5-18 | — | — |
| Reference | Tews et al | Elliott et al. | Jazrawl et al. | N/A | N/A |
| | (2014); | (2013a) | (2013); | | |
| | NABC (2014) | | Elliott et al. | | |
| | | | (2013b) | | |

*daf = dry, ash free

Overall carbon yield, including hydrotreatment of the biocrude product, was nearly 50 percent, with the resulting product exhibiting a large fraction in the distillate range. These results are based on lignocellulosic feedstock, and the results could be significantly different for other biomasses, such as algae, with high nitrogen contents.

### Hydrothermal Carbonization Technology

Hydrothermal carbonization (HTC) is a thermochemical conversion process that uses heat to convert wet biomass feedstocks to hydrochar. HTC is performed at about 180 to about 250° C., under autogenous (automatically generated) pressure, with residence time ranging from about 0.5 to about 8 hours. The major advantage of HTC over other high temperature thermochemical conversion techniques such as pyrolysis, is the HTC process treats wet waste, which allows feedstocks to be converted without pre-drying. Certain system and method embodiments described herein in accordance with the present disclosure are explicitly recited as without any biomass drying unit operations, and without any biomass drying process steps, meaning that there is no added energy to the system for drying the wet biomass. Other embodiments may be recited as “without substantial biomass drying”, meaning that an initially wet biomass may be dried a de minimis amount prior to entering the system merely by the action of the sun on a hot day, or in other relatively hot atmospheric conditions.

A wide variety of feedstocks, including aquatic biomass, agricultural residues, and industrial and animal wastes, are suitable. Water acts as a good medium for heat transfer in HTC, but if variability in the feedstock particle size is too large and reaction time is too short, there might be some mass transfer limitations. Hence, the particle size should be homogeneous or nearly so to promote uniform heat and mass transfer.

A relatively small amount of gases (primarily CO₂) and an aqueous slurry are produced. The aqueous slurry is centrifuged or filtered to separate the process water and solids (wet cake) to produce a carbon-rich hydrochar. The wet cake can be further dried and pelletized depending upon final use.

Multiple reactions occur during the HTC process, namely hydrolysis (reaction with water), dehydration (removal of water), decarboxylation (removal of carboxyl groups which results in the liberation of CO₂), and aromatization (formation of aromatic compounds). These reactions occur under high temperature and pressure and play a vital role in lowering the hydrogen to carbon (H/C) and oxygen to carbon (O/C) ratios to produce the carbon-rich hydrochar.

Hydrochar yield depends upon the type of feedstock, the solids loading (ratio of feedstock to water), and the process temperature and residence time (Table 3, from Hydrothermal Carbonization: Upgrading Waste Biomass to Char, originally posted Jan. 11, 2021, Shyam Sivaprasad, Graduate Research Associate, Dr. Ashish Manandhar, Postdoctoral Researcher, Dr. Ajay Shah, Associate Professor, Department of Food, Agricultural and Biological Engineering, The Ohio State University.

Hydrochar yield decreases with increased severity of process conditions, in other words, higher temperature and longer residence time, which decomposes more of the cellulosic and hemicellulosic fractions in the feedstock. (Gallant, R.; Farooque, A. A.; He, S.; Kang, K.; Hu, Y., A Mini-Review: Biowaste-Derived Fuel Pellet by Hydrothermal Carbonization Followed by Pelletizing, Sustainability, 2022.

Despite lower yield, at higher temperatures and longer residence times, the hydrochar has a higher carbon content with a higher heating value (HHV). J González-Arias, M E Sánchez, E J Martínez, C Covalski, A Alonso-Simón, R González, J Cara-Jiménez, Hydrothermal Carbonization of Olive Tree Pruning as a Sustainable Way for Improving Biomass Energy Potential: Effect of Reaction Parameter on Fuel Properties (2020) At 220° C., hydrochar yields were the highest but longer residence times were required to reduce O/C ratio and increase heating value. At 280° C., hydrochar yields were the lowest but had highest heating value although the improvements were minimal over 250° C. For the purposes of scaling and operational efficiency, the optimum temperature and residence time occurs at 250° C. at 3 hours where the hydrochar has an O/C of <0.3 and HHV of 27.9 MJ/kg. Thermal degradation of cellulose and hemicellulose could lead to the formation of water-soluble organic acids such as levulinic acid, formic acid, lactic acid and acetic acid; and thus, would lower the yield of hydrochar but increase the yield of the aqueous phase. These organic acids can then be further separated or extracted or distilled for creating additional valuable byproducts from the HTC process.

TABLE 3
Hydrochar yields for various feedstocks
under different HTC conditions

| Feedstock | Feedstock | | Residence | Hydrochar |
|---|---|---|---|---|
| source | type | Temp., (° C.) | time (min) | yield (%) |
| Forest | Jeffrey pine | 250-275 | 30 | 51-69 |
| | and white | | | |
| | fir (Tahoe | | | |
| | mix) | | | |
| Industry | Sawdust | 250 | 120 | 40 |
| | Sewage | 250 | 30 | 68-76 |
| | sludge | | | |
| Agriculture | Palm shell | 180-260 | 30-120 | 39-71 |
| | Palm | 150-250 | 20 | 62-76 |
| | residue | | | |
| Aquatic | Microalgae | 190-210 | 30-120 | 25-46 |
| Animal | Dairy | 180-260 | 240 | 35-57 |
| waste | manure | | | |

### Comparison of Hydrochar and Biochar

Wet feed pyrolysis requires very high energy costs to pre-dry the wet biomass feedstock and is uneconomical with wet slurry biowastes. Table 4 provides a comparison of hydrochar produced by HTC and biochar produced by pyrolysis. Table 5 provides a list of potential advantages of HTC over pyrolysis.

TABLE 4
Comparison of Hydrochar and Biochar

| | Hydrochar | |
|---|---|---|
| | (hydrothermal | Biochar |
| Characteristic | carbonization) | (pyrolysis) |
| Production | Hydrothermal | Pyrolysis process |
| method | carbonization process | |
| Feedstock | High moisture biomass | Dry biomass (e.g., wood, |
| | (e.g., sludge) | agricultural residues) |
| Production | Moderate temperatures | High temperatures |
| temperature | (180-250° C.) | (400-800° C.) |
| Production | High pressure (up to 70 | Atmospheric pressure |
| pressure | bar) | |
| Moisture | Higher moisture content | Lower moisture content |
| content | (typically 50-80%) | (typically <20%) |
| Carbonization | Relatively shorter | Longer carbonization |
| time | carbonization time | time |
| Structure | Amorphous | Crystalline or semi- |
| | | crystalline |
| Porosity | Higher | Lower |
| pH level | Typically neutral or | Neutral to alkaline |
| | slightly acidic | |
| Nutrient | Relatively higher | Lower |
| content | | |
| Carbon | Potential carbon | Considered as a method |
| sequestration | sequestration value | for carbon sequestration |
| | | and climate change |
| | | mitigation |
| Energy | Lower energy-intensive | Higher energy-intensive |
| intensity | process | process |
| Market | Emerging technology | Established technology |
| maturity | | |

Table 5. Advantages of HTC over Pyrolysis

| | Hydrothermal | |
|---|---|---|
| Advantages | carbonization | Pyrolysis |
| Feedstock flexibility | Can process high-moisture and | Requires low-moisture |
| | wet biomass | feedstock |
| Energy efficiency | Operates at moderate | Requires high temperatures for |
| | temperatures and pressure. | reaction. |
| | Can utilize simple, readily | Requires complex and |
| | available and high efficiency | inefficient heat exchangers to |
| | heat exchangers for energy | recover energy from process |
| | recovery from process streams. | streams. |
| Product yield | Yields hydrochar with higher | Yields biochar and bio-oil |
| | energy content | |
| Process simplicity | Simple process with minimal | Complex process with multiple |
| | off-gases. Only requires liquid- | products with multiple phases. |
| | solid separation. | |
| Carbon sequestration | Hydrochar has a higher carbon | Biochar also offers carbon |
| | sequestration potential due to | sequestration but at lower |
| | higher biomass conversion | yields. |
| | yields | |
| Byproduct utilization | Liquid byproducts can be used | Byproducts have limited |
| | as fertilizers or chemicals | applications |
| Environmental Impact | Lower fugitive emissions, dust | Higher emissions, combustible |
| | and reduced odor during | char and potential odor issues |
| | processing | |
| Feedstock preparation | Minimal preprocessing required | Requires extensive drying of |
| | for wet feedstock | feedstock |
| Scalability | Scalable to smaller | Suitable for larger centralized |
| | decentralized systems thereby | facilities. |
| | increasing catchment area. | |
| | Lower transportation distance. | |

### Benefits of HTC and Hydrochar

Avoids feedstock pre-drying: HTC does not require pre-drying of biomass and can utilize feedstocks of varying moisture contents, which saves energy and costs for drying before processing. This is one of the major benefits of HTC compared to other thermochemical processing methods that require dry feedstocks to produce char.
Enhanced hydrophobicity: The hydrochar has less moisture and is more hydrophobic than raw feedstock. These attributes separate more water through mechanical separation equipment, decrease transportation costs and improve shelf life by impeding wettability and rot during storage.
High nutrient recovery: HTC promotes enhanced nutrient recovery as both solid (hydrochar) and process water possess essential nutrients, including phosphorus, potassium and nitrogen, which are vital for plant growth.
Improved dewatering efficiency: HTC enhances the dewatering efficiency of raw feedstocks as it helps release the bound water and thus is highly beneficial for biosolids management. If dewatered or dried hydrochar must be disposed, the cost of transport and disposal is significantly reduced.
Lower environmental impact: HTC has the potential to minimize environmental impacts of waste biomass as it recovers more energy, and emits much less pollutants and odor, than incineration, landfilling, and composting [19]. Generates 6.2× more energy than it consumes. Generates minimal gases compared to other thermochemical conversion technologies.
Reduces pharmaceuticals & PFAS chemicals: WWTP sludge contains contaminants such as pathogens, pharmaceuticals and highly stable carcinogen compounds. These contaminants can be significantly reduced or eliminated through HTC. Table 6 lists some pharmaceuticals and their destruction by HTC.
Operates on electrical power: HTC conversion process can be operated on electrical power which can be easily sourced from low carbon and renewable energy.
High char conversion: HTC generates minimal gases and highest yields compared to other thermochemical conversion processes.
Onsite Operations: HTC systems can be economical for small biowaste generators such as a WWTP site for a population of 200,000-400,000

TABLE 6
Destruction of Pharmaceuticals by HTC

| | Measured concentration | Concentration | Removal |
|---|---|---|---|
| | in spiked sewage sludge | after HTC | during HTC |
| | μg/kg_{DM} | μg/kg_{DM} | % |
| Ibuprofen | 350 ± 33 | 130 ± 15 | 63 |
| Phenazone | 210 ± 33 | 230 ± 6 | No removal |
| Carbamazepine | 560 ± 23 | <20 | >98 |
| Bezafibrate | 180 ± 8 | <40 | >89 |
| Fenofibric acid | 340 ± 23 | <20 | >97 |
| Metoprolol | 650 ± 96 | 400 ± 23 | 39 |
| Propranolol | 360 ± 120 | 70 ± 14 | 81 |
| Clarithromycin | 220 ± 55 | <20 | >95 |
| Roxithromycin | 190 ± 63 | <10 | >97 |
| Erythromycin | 180 ± 24 | <10 | >98 |

### Environmental Contaminant Reduction

As illustrated in Table 7, there is no significant concentration of PFAs in biochar produced from sewage sludge.

TABLE 7
PFAs in hydrochar

| | | Concentration | | |
|---|---|---|---|---|
| | | in sewage | Concentration | Threshold limit |
| | Unit | sludge | in biochar | values |
| Polycyclic aromatic | mg/kg_{DM} | 2.02 | 3.30 | 20* |
| hydrocarbons (PAH) | | | | |
| Polychlorinated biphenyls | mg/kg_{DM} | 0.02 | 0.03 | 0.20** |
| (PCB) | | | | |
| Polychlorinated dibenzo- | ng TEQ/kg_{DM} | 3.35 ± 2.3 | 18.7 ± 1.7 | 100** |
| dioxins and furans (PCDD/F) | | | | |

*draft version for biochar specification guidelines, International Biochar Initiative [23]
**German sewage sludge ordinance [24]

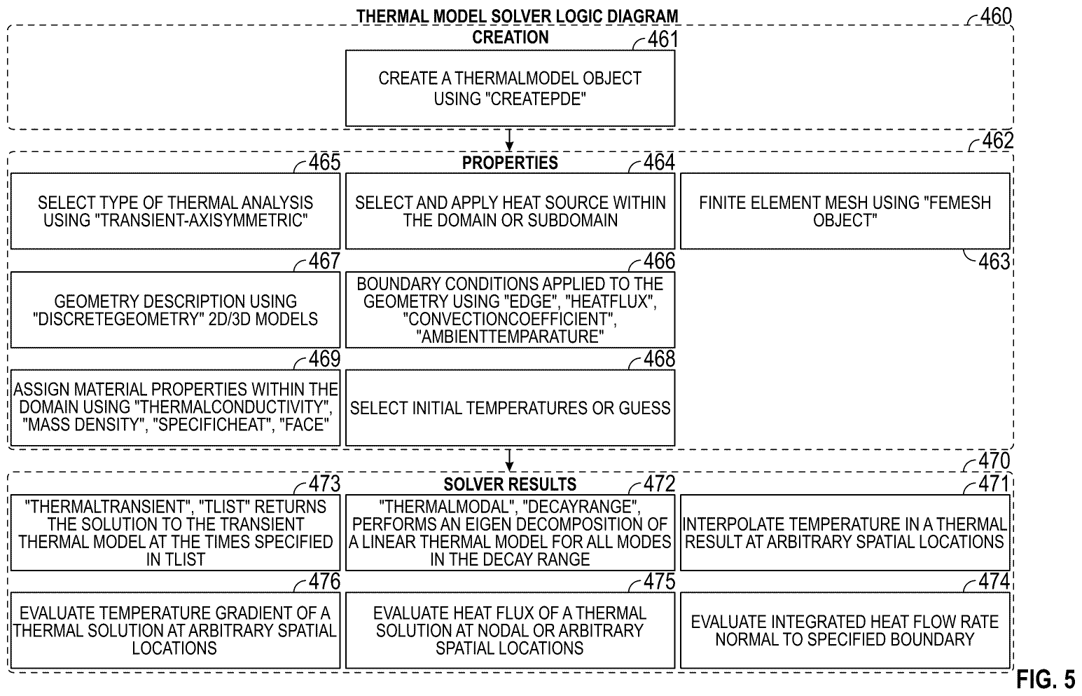

As illustrated in FIG. 5 of our co-pending '486 patent application, HTC offers great reduction in PFAs. Pre-investigations of micropollutant load in sewage sludge and hydrochar from hydrothermal carbonization (HTC) of sewage sludge. HTC was carried out for four hours at 210° C. and 15 bar with sewage sludge from the wastewater treatment plant Hollenstedt, Germany (Eyser, C.V. (2016). Behavior of micropollutants during hydrothermal carbonization of sewage sludge.)

### Drawbacks of HTC and Hydrochar

Drying of hydrochar: After mechanical separation and dewatering of hydrochar, some applications require drying and pelletization. The drying step is energy intensive consuming more than the HTC process itself.
Contaminants: Depending upon the feedstock used, the products may also contain undesirable metals, such as Ni, Pb, Cd, Cr, which are distributed among solid and liquid fractions post HTC.
Dissolved organics in water phase: The formation of acidic compounds such as acetic, levulinic, formic, and lactic acids may result in pH as low as 3.6. While this makes it easier to hydrolyze biomass, the excess water must be treated requiring aerobic or anaerobic digestion and neutralization, or return to WWTP. Neutralized treated water is beneficial as a fertilizer.

Typical heavy metal concentrations in WWTP sludge are illustrated in Table 8.

TABLE 8
Typical heavy metal concentrations in WWTP sludge

| | Concentration | Criteria |
|---|---|---|
| | (mg/kg) | (mg/kg)* |
| Lead (Pb) | 10-150 | 300 |
| Cadmium (Cd) | 0.5-5 | 85 |
| Mercury (Hg) | 0.1-1 | 17 |
| Chromium (Cr) | 10-100 | 3,000 |
| Arsenic (As) | 5-40 | 75 |
| Nickel (Ni) | 10-100 | 420 |
| Copper (Cu) | 100-1,000 | 1,500 |

*United States Environmental Protection Agency (EPA) Part 503 regulations, the maximum allowable concentrations of certain heavy metals in biosolids for land application

### Modeling Methods and Computer-Readable Media of the Present Disclosure

The modeling methods and computer-readable media of the present disclosure model the systems and methods of our co-pending applications and equivalents thereof. The HTL systems and methods being modeled continuously convert biomass at high volumetric flow rates into biocrude using hydrothermal liquefaction while minimizing hydrothermal carbonization. The HTC systems and methods being modeled continuously convert biomass at high volumetric flow rates into hydrochar using hydrothermal carbonization. Biomass is prepared to generate a biomass slurry for HTL or HTC processing as the case may be. Certain HTC embodiments may comprise pumping the biomass slurry at a flow rate of about 175 to about 225 tons per day into the inner tube at pressure ranging from about 75 to about 125 psi to a depth of about 650 to about 750 m (length of the inner tube) and product fluid returned to the surface in the annulus. An electrically heated cable is located at the bottom of the inner tube and operated to preheat the incoming fluid, in certain embodiments up to about 250° C. Preheating comes from the countercurrent flow of hot product fluid in the annulus, the inner and outer tubes essentially forming a tube in tube heat exchanger. The product fluid comprising hydrochar then moves up the annulus along with water and some gases, at less than 5% of biomass (CO₂ mostly with some CH₄). As discussed herein, HTL requires very high pressures and temperatures, for example from about 2,500 psi to about 3,500 psi and from about 250° C. to about 350° C., or from about 2,700 psi to about 3,300 psi and from about 275° C. to about 325° C., or about 3,000 psi and about 300° C. These temperatures and pressures are very challenging operating conditions particularly under continuous processing conditions. In previously known HTL systems and processes, specialized pumps, depressurizing valves and pressure recovery, heat exchangers not commercially available, exotic metallurgy and atypical wall thicknesses were required. In addition, there are numerous issues related to excessive wear and tear, safety, redundancy requirements and very high costs. In particular, at least some of the high thermal energy required to heat the feed biomass slurry to the desired HTL temperatures should be recovered for economic viability. Ordinarily this would require heat exchangers capable of operating at the target HTL temperatures and pressures which are not commercially available for the relatively high processing rates.

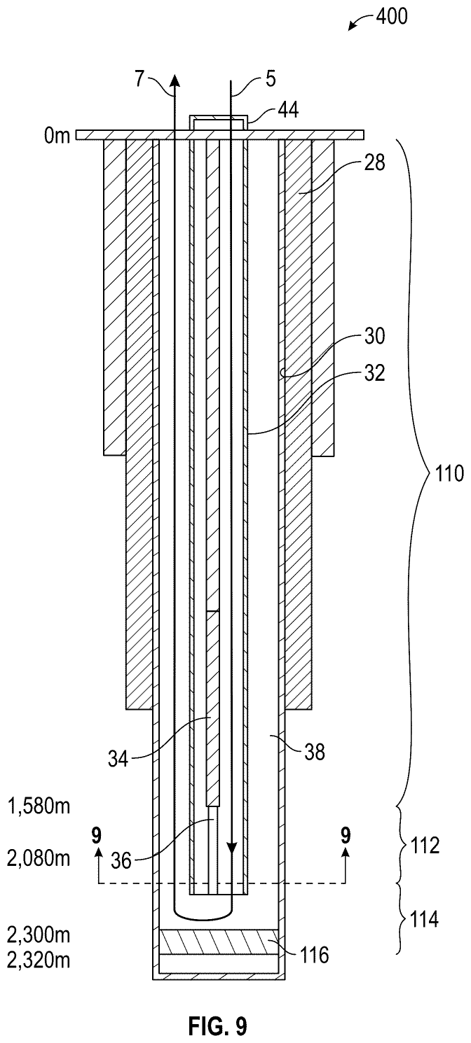

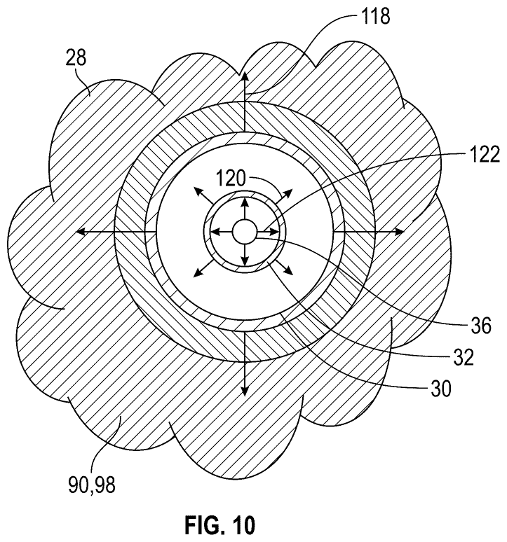

At this time, globally, there are no commercial scale HTL or HTC operations, largely due to these challenges. To overcome many of these challenges, the modeling methods described herein model systems and methods utilizing a deep well (and therefore referred to herein as “well reactors”), in certain embodiments deep wells commonly drilled and constructed for oil and gas production. These deep wells can safely and inexpensively generate the high pressures required via hydrostatic pressure by using commonly available metallurgy, dimensions and geometry. The depth of the well determines the pressure. In certain HTL embodiments, as in embodiment 400 illustrated schematically in FIGS. 9 and 10, the well includes an inner tubing 32 and an outer tubing (casing) 30 where the feed slurry enters inner tubing 32 at the top 44 of the well at the surface and flows to the bottom portion of the well, and product fluid 7 returns to the surface in an annulus 38 formed between inner tubing 32 and casing 30. No high-pressure submersible pumping is required as the systems and methods take advantage of the hydraulic U tube effect and hydrostatic pressure simultaneously. Biomass slurry 5 is heated at the bottom of the well to the target temperature by a heating element 36 of an electric cable 34 but prior to reaching bottom portion of the well, while product fluid 7 returning in annulus 38 preheats the incoming biomass slurry 5. The majority of the heat in product fluid 7 is recovered via the transfer of thermal energy from the hot product fluid 7 flowing upward in annulus 38 to the incoming cold feed biomass slurry 5 in a heat transfer and separation zone. In modeling systems and methods of the present disclosure, the temperature of the preheated feed slurry in inner tubing 32 is boosted at bottom portion (HTL reaction zone) of the well under pressure to ensure the biomass slurry fluid remains as a liquid for the hydrothermal liquefaction reactions to occur. The deep well will essentially be our reactor. The heat source comes from the submersed electrical resistance heater cable (34, 36 powered by a power source, which may employ grid power or other power) which is commonly used in oil and gas production to reduce viscosity of heavy oils and waxes, flow assurance and to increase production or other methods of heating inner tubing 32. FIGS. 9 and 10 are discussed more fully herein below.

Certain modeling methods of the present may employ: (a) energy recovery; (b) feed slurry preheating; c) boost heating to reach HTL temperature; and d) drilling fluid and/or cements having insulating properties to minimize heat losses. Some or all of these may be satisfied by the design of specific thermal components, as well as configuration design of the processing systems. In certain embodiments, thermal management in systems and embodiments of the present disclosure may include one or more of the following components: (1) a heat exchanger which is designed to ensure the thermal energy recovery with primary functions of feed biomass slurry preheating and product fluid cooling; (2) the electrical heater, which serves to boost the temperature after pre-heating; and (3) the well reactor where the majority of chemical HTL reactions occur.

### Modeling of Well Reactor & Surface Separation of Biomass Conversion Process

The following discussion is written with modeling of HTL processes in mind. It should be noted that the modeling methods for HTC systems and methods are similar. Modeling can be broken down into four general modules, each providing an input and output used by each module with the starting point being a biomass and end point being converted biomass products. The entire process can be modeled with a mass and energy balance at steady state conditions with the exception of the energy loss to the subsurface which will be discussed further herein.

The process can be broken out into four main modules:
1. Feed Receiving, Storage and Preparation Module
2. Feed Slurry, Mix and Pump Module
3. Deep Well Reactor Module
4. Gas-Liquid-Sludge Separation & Storage Module

The overall process includes equipment at both surface and subsurface. In certain embodiments the surface and subsurface equipment are fully integrated, but that is not required in order to practice the systems, methods, and modeling methods of the present disclosure. Overall, systems, methods, and modeling methods of the present disclosure may be described at a high level as taking in biomass materials and outputting four products (in the case of HTL): bio-crude, process water, process gas and sludge. In the case of HTC, the products are similar except hydrochar is produced rather than biocrude.

Modeling modules 1, 2 and 4 may be modeled individually or together, and can be made with basic flow diagrams, mass transfer equations, phase changes based on temperature and pressure conditions, mechanical attrition of feedstock, mechanical separation, and key assumptions.

Module 3 is a combination of steady state and transient conditions. Mass transfer is modeled at steady state and modeling methods involve the conversion of biomass to biocrude or hydrochar and gases at certain reaction kinetics which may be modeled with key coefficient assumptions as the biomass slurry moves through the inner tube and product fluid returns in the annulus inside the wellbore. However, heat transfer models are a combination of steady state and unsteady state (transient) modeling. Heat transfer that occurs within the wellbore is steady state, however heat loss to the formation is transient. The simulations and modeling methods of the present disclosure utilizes one or more graphical user interfaces (GUIs) for data input and output, otherwise referred to as human/machine interfaces (HMIs). One or all outputs may be displayed in locally on one or more HMIs, such as a touchscreen display or similar. In certain embodiments an HMI may record and/or transmit the data via wired or wireless communication to another HMI, such as a laptop, desktop, or hand-held computer or display.

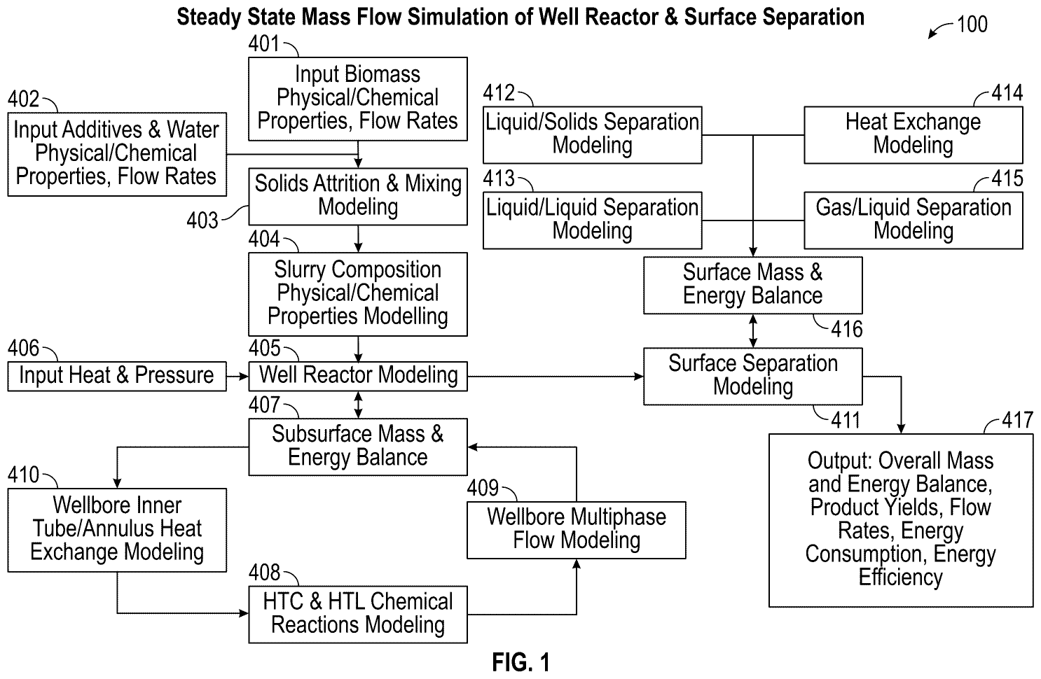

FIG. 1 illustrates a schematic logic diagram of an integrated modeling method embodiment 100, including all four modules, and the flow of input parameters and outputs along with subsystems requiring their own models. Embodiment 100 of FIG. 1 models steady state mass flow of a well reactor and surface separation systems, such as illustrated. Embodiment 100 includes (in no particular order) (a) selecting flow rate, physical properties, and chemical properties of a biomass slurry precursor composition (box 401); (b) selecting one or more chemical additives to be mixed therewith (box 402); and (c) selecting operating parameters of solids attrition and mixing equipment, (box 403). Method of modeling embodiment 100 comprises modeling formation of a biomass slurry using data input from steps (a)-(c) (box 404). A well reactor and hydrothermal reactions are then modeled (box 405), the well reactor comprising: 1) one or more tubing positioned inside a casing of a well in a subterranean formation, the well having a well depth, a well top positioned at a surface location, and a bottom portion positioned at a subterranean location, the casing and the one or more tubing positioned therein forming an annulus there between; 2) the casing and the one or more tubing defining an HTL or HTC reaction zone in the bottom portion of the well and a heat transfer and separation zone above the HTL or HTC reaction zone; and 3) one or more cables each comprising an electric heating element positioned in respective one or more of the one or more tubing, the heating element positioned in the HTL or HTC reaction zone. Heat input and pressure are input as indicated in box 406.

Modeling method embodiment 100 further includes modeling subsurface mass and energy balances (box 407), including modeling the biomass slurry continuously flowing into the top of the well at a first temperature and a first pressure, and flowing downward through at least one of the one or more tubing, to form a continuously flowing biomass slurry stream; modeling heating of the continuously flowing biomass slurry stream in the HTL or HTC reaction zone (HTC and HTL chemical reactions modeling, box 408) employing the electrical heating element; and modeling a multiphase, continuously flowing product fluid stream (box 409) comprising biocrude oil produced by converting at least a portion of the continuously flowing biomass slurry stream into the biocrude oil by HTL in the HTL reaction zone (or the hydrochar by HTC in the HTC reaction zone) the well depth and the electrical heating element configured to produce a second temperature and a second pressure in the HTL or HTC reaction zone sufficient to form sub-critical water but insufficient to form supercritical water, the multiphase, continuously flowing product fluid stream flowing upward through the annulus and thermally interacting with the continuously flowing biomass slurry stream flowing downward through the one or more tubing. Modeling subsurface mass and energy balances (box 407) includes modeling heat transfer between the multiphase, continuously flowing product fluid stream, the well, and the formation, and optionally through the casing and casing construction materials, using a first equation; modeling heat transfer between the multiphase, continuously flowing product fluid stream and the continuously flowing biomass slurry using a second equation (modeled as indicated in box 410), and modeling heat transfer between the heating element and the continuously flowing biomass slurry using a third equation, wherein the first equation, the second equation, and the third equation form a coupled system of equations. The modeling method 100 performs a mass and energy balance for the well reactor and the subterranean formation by solving the coupled system of equations numerically, providing heat transfer rates to determine the pressure, temperature and quality profile in the continuously flowing product fluid stream.

Method of modeling embodiment 100 may further comprise modeling and performing a mass and energy balance for a surface separation system (box 411), which may include modeling liquid/solids separation (box 412), liquid/liquid separation (box 413), heat exchanger modeling (box 414), and gas/liquid separation modeling (box 415), to model a surface mass and energy balance (box 416). Modeling method 100 may further comprise performing an overall mass and energy balance for the well reactor, the subterranean formation, and the surface separation system, as indicated in box 417.

In one embodiment, the material balance of one system and method embodiment of the present disclosure includes feed biomass slurry stream 5 including 215 metric tons/day biomass slurry, which included 44 metric tons/day biomass, 168 metric tons/day water, and 9 metric tons/day solids. A recovered gas stream included 6.4 metric tons CO₂ and 0.6 metric tons/day CH₄. An HTL products fluid stream 7 included 17.1 metric tons/day biochar, 20 metric tons/day biocrude, 163 metric tons/day water, and 9 metric tons/day solids. A recovered water stream was 147 metric tons/day, while an HTL sludge stream included 17.1 metric tons/day biochar, 25.8 metric tons/day water, and 6.8 metric tons/day solids. Finally, a recovered biocrude stream was 15.7 metric tons/day.

### Heat Transfer Analysis and Modeling

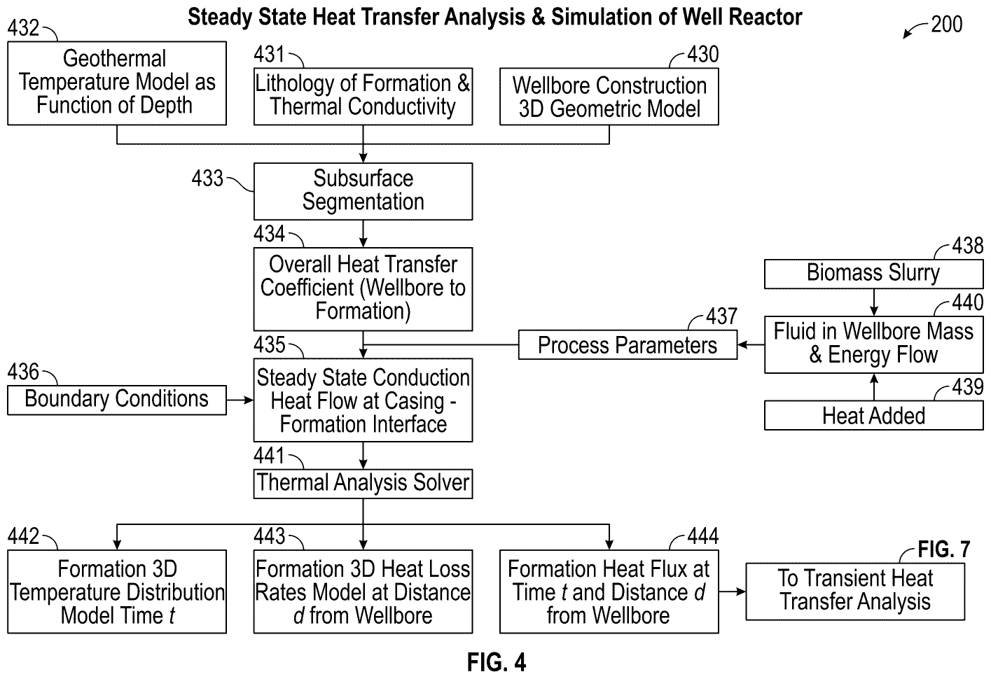

Steady state heat transfer (FIGS. 2, 4, and 5) within a selected well design 430 in a selected subterranean formation can be modeled and calculated with heat transfer equations along with inputs including subsurface lithology 431, subsurface temperature vs. depth (geothermal temperature model, 432), well construction details (for example cements, tubing and casing materials, insulating fluids, and the like), target temperatures of the heated biomass slurry, and processing parameters such as mass flow rates and physical properties of the biomass slurry as shown above. The modeling methods of the present disclosure, however, become more complex to adjust for any changes to each input parameter by segmenting (box 433 in FIG. 4, and FIG. 5) to accommodate each change in lithology L1, L2, L3, Lx, and change in overall thermal resistance R₁, R₂, R₃, Rₓ at each segment S₁, S₂, S₃, Sₓ, which become inputs to the heat transfer equations, as illustrated herein.

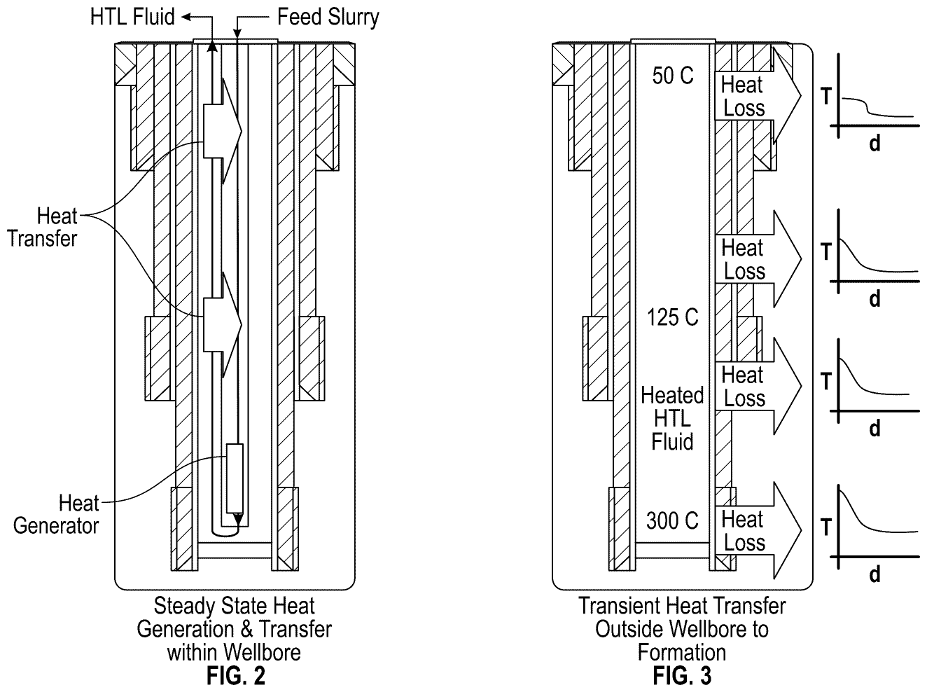

In reality, heat losses from wells never reach a steady state (FIG. 3). In most embodiments, they attain a quasi-steady state (which may be modeled) in which the rate of heat loss is a monotonically decreasing function of time (absent unusual circumstances, such as geothermal activity). Methods of modeling of the present disclosure, when modeled using monotonically decreasing function of time, measure of how fast the formation conducts heat away from the well. In these embodiments, the specific thermal resistance of the formation is time dependent, reflecting the variable effective thermal resistance of the formation. A representation of the typical elements offering resistance to heat losses from the wellbore is given in FIGS. 3, 6, and 7.

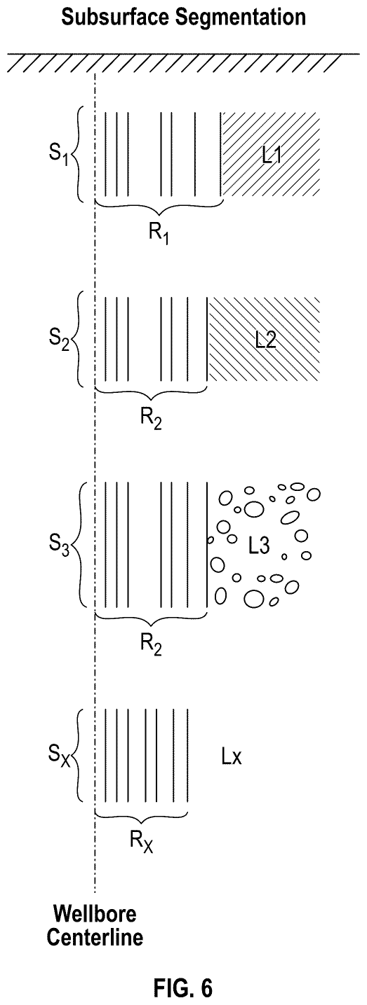

The basic equation used to calculate heat losses per unit length of pipe, Qₗₛ, is Equation 1:

$${Q}_{ls} = \frac{{T}_{b} - {T}_{a}}{{R}_{h}} \qquad ( 1 )$$

where T_{b} is temperature of product fluid flowing in the annulus, T_{A} is the temperature of the formation, Rₕ is the specific thermal resistance (thermal resistance per unit length of pipe). Different well designs lead to different expressions for determining the overall thermal resistance Rₕ, which is calculated with Equation 2:

$${R}_{h} = \frac{1}{2 π rU} \qquad ( 2 )$$

wherein “r” is an arbitrary radius that usually coincides with the radius of one of the surfaces for which the heat loss is being determined, and U is the overall coefficient of heat transfer. Rates of heat loss during transient periods can be several times greater than at steady state. For a wellbore containing multiple pipes, cement, fluids, and the like, the specific thermal resistance of heat loss is graphically presented in FIG. 6, and Equation 3.

$${R}_{h} = \frac{1}{2 π} [ \frac{1}{{h}_{fa} {r}_{3}} + \frac{1}{{λ}_{2}} ln \frac{{r}_{3}}{{r}_{4}} + \frac{1}{{λ}_{3 a / b}} ln \frac{{r}_{4}}{{r}_{5}} + \frac{1}{{λ}_{4}} ln \frac{{r}_{5}}{{r}_{6}} + \frac{1}{{λ}_{5 a / b}} ln \frac{{r}_{6}}{{r}_{7}} + \frac{f ( {t}_{D} )}{{λ}_{6}} ] \qquad ( 3 )$$

wherein:
h_{ƒi}—film coefficient of heat transfer (boundary condition, FIG. 4, box 436) between the fluid inside the inner production tubing and tubing wall;
h_{ƒo}—film coefficient of heat transfer (boundary condition) between the fluid outside of the inner production tubing in the annulus;
h_{ƒa}—film coefficient of heat transfer (boundary condition) between the fluid in the annulus and the inside the outer pipe casing;
r₁ inner radius of the inner production tubing;
r₂ is the outer radius of the inner production tubing;
r₃ is the inner radius of the outer pipe casing No. 1;
r₄ is the outer radius of the outer pipe casing No. 1;
r₅ is the outer radius of the drilling fluid and/or cement;
r₆ is the inner radius of the outer pipe casing No. 2;
r₇ is the outer radius of the drilling fluid and/or cement;
λ₁—thermal conductivity of the inner production tubing;
λ₂—thermal conductivity of the outer pipe casing No. 1;
λ_{3a/b}—thermal conductivity of drilling fluid and/or cement;
λ₄—thermal conductivity of the outer pipe casing No. 2;
λ_{5a/b}—thermal conductivity of drilling fluid and/or cement; and
λ₆—Thermal conductivity of formation.
ƒ(t_{D}) is the time function that reflects the thermal resistance of the formation, ƒ(t_{D}) terms of dimensionless time (Equation 4):

$${t}_{D} = \frac{{α}_{F} t}{{r}_{F}^{2}} \qquad ( 4 )$$

where α_{F} is the thermal diffusivity of the formation in area per time (m²/hr.), and t is the time from start of heating in hours. The film coefficients in turn depend on process parameters such as type and consistency of biomass slurry (box 438) and heat added to the biomass slurry (box 439) contributing to wellbore fluid mass and energy flow (box 440).

In order to solve for heat loss to the surroundings that reflects the pseudo-steady state heat flow conditions in the wellbore, the rate of heat conduction from the fluid to the outer edges of the cement-formation interface is expressed as in Equation 5:

$$\frac{dq}{dz} = 2 π {r}_{to} ( {T}_{f} - {T}_{h} ) \qquad ( 5 )$$

and the rate of heat conduction to the formation (FIG. 4, box 435) is expressed as (Equation 6):

$$\frac{dq}{z} = \frac{2 π {k}_{f} ( {T}_{h} - {T}_{f} )}{f ( t )} \qquad ( 6 )$$

wherein:
T_{f} is the temperature of the formation,
Tₕ is the temperature of the wellbore,
k_{ƒ} is the thermal conductivity of the formation, and
ƒ(t) is the time conduction function.

Because the rate of heat conduction from the fluid to the cement formation interface (hole) must equal the rate of heat conduction into the earth then Tₕ can be expressed as (Equation 7):

$${T}_{h} = \frac{{r}_{to} {U}_{to} f ( t ) {T}_{f} + {k}_{f} {T}_{f}}{{r}_{to} {U}_{to} f ( t ) {T}_{f} + {k}_{f}} \qquad ( 7 )$$

where Uₜₒ is the overall heat transfer coefficient or the overall coefficient of conductance (FIG. 4, box 434). The heat loss to the formation can be expressed as follows (Equation 8):

$$\frac{dQ}{dz} = \frac{2 π {r}_{to} {U}_{to}}{Wm} [ {T}_{f} \frac{{r}_{to} {U}_{to} f ( t ) {T}_{f} + {k}_{f} {T}_{f} ( Tm + az )}{{r}_{to} {U}_{to} f ( t ) {T}_{f} + {k}_{f}} ] \qquad ( 8 )$$

Using the geothermal gradient, the temperature of the formation, T_{ƒ}, is given by Equation 9:

T_{f}=Tₘ+az (9)

wherein:
Tm is the mean surface temperature,
a is the geothermal gradient (° C./m), and
z is the depth (m).
Wₘ is the energy added to the fluid in the annulus.

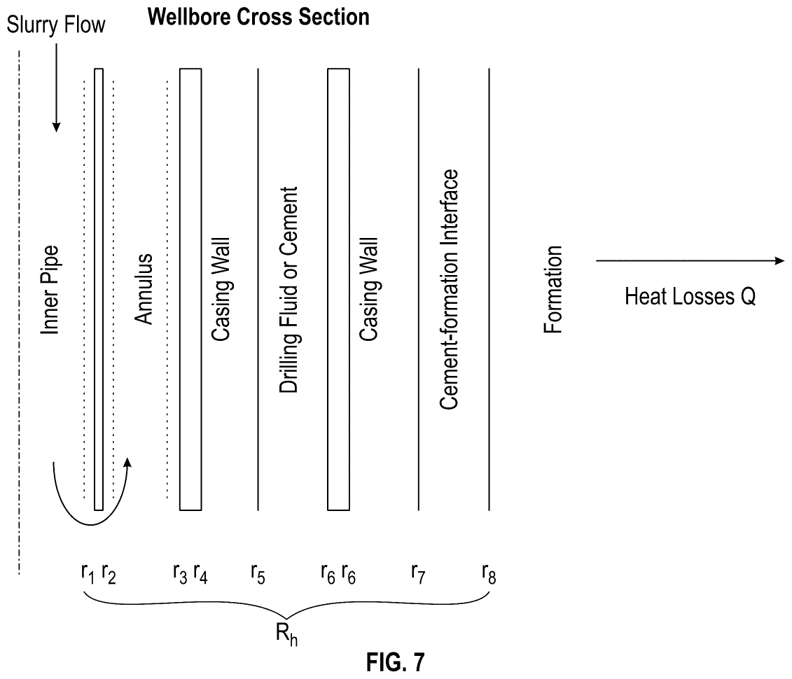

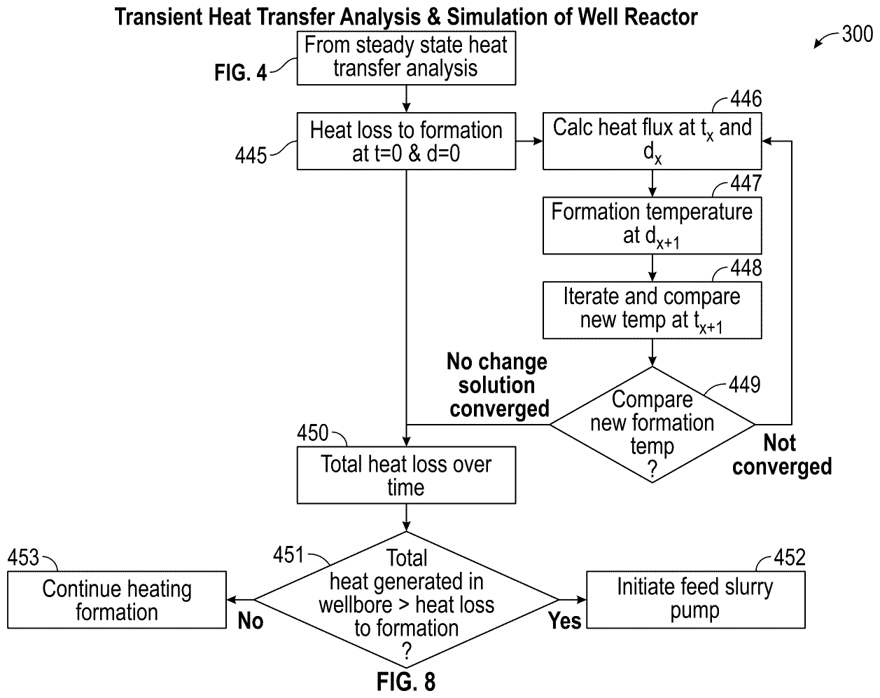

The time conduction function ƒ(t) introduced in the equation of unsteady state (transient) heat flow to the formation needed to obtain dQ/dz and Uₜₒ can be estimated from solutions for radial heat conduction from an infinitely long cylinder. The convergence time may be on the order of one week for many embodiments. This is illustrated schematically in the logic diagram of FIG. 7 for model embodiment 300, where heat loss to the formation at time t=0 and distance d=0 from the wellbore (box 445) is used calculate heat flux and formation temperature Tₓ at selected time tₓ and selected distance dₓ (box 446) which is then used to calculate formation temperature Tx+1 at a time tx+1 and a distance dx+1 using the formation temperature Tx and calculated heat flux at time tₓ and distance dₓ (box 447). Method embodiment continues iteratively in comparing Tₓ with Tₓ₊₁ (box 448, 449) and if not equal, return to box 446, and if equal use Tₓ₊₁ to calculate total heat loss to the formation over time tₓ₊₁ (box 450). Method embodiment 300 further comprises comparing (box 451) total heat input generated in the wellbore with heat loss to the formation, and if the value of total heat that would be generated in the wellbore from hydrothermal reactions in the wellbore is greater than the total heat loss to the formation over time, initiating (box 452) a simulated biomass slurry pumping into the one or more tubing of the wellbore construction 3D geometric model; and if the value of total heat that would be generated in the wellbore from hydrothermal reactions in the wellbore is less than the total heat loss to the formation over time, continue heating the wellbore construction 3D geometric model (box 453). Thus, the line source solution will often provide useful results if times are greater than a week. An approximate equation for ƒ(t) satisfying the line source solution to the diffusivity equation for long times is (Equation 10):

$$f ( t ) = - ln ( \frac{{r}_{h}}{2 \sqrt{α t}} ) \qquad ( 10 )$$

Referring again to FIG. 4, a thermal analysis solver (computer program algorithm, box 441) may then be used to model one or more of formation 3D temperature distribution at time t (box 442), formation 3D heat loss rate at distance d from wellbore (box 443), and formation heat flux at time t and distance d from wellbore (box 444). FIG. 5 illustrates schematically a logic diagram for one thermal analysis solver 441 that may be used, known under the trade designation MATLAB, including a Creation module 460 that includes creating a “ThermalModel” object using “creatpde” (box 461), a Properties module (box 462), and a Solver Results module (box 470). The software known under the trade designation MATLAB is a high-level matrix/array language with control flow statements, functions, data structures, input/output, and object-oriented programming features, and is a proprietary multi-paradigm programming language and numeric computing environment developed by MathWorks. It can be used to solve conduction dominant heat transfer problems with convection and radiation occurring at boundaries. The heat transfer equation is a parabolic partial differential equation that describes the distribution of temperature in a particular region over given time. A typical programmatic workflow for solving a heat transfer problem includes the following steps. These are described in more specificity using MATLAB functions in FIG. 5:
Create a special thermal model container for a steady-state or transient thermal model.
Define 2-D or 3-D geometry and mesh it.
Assign thermal properties of well construction and formation materials, such as thermal conductivity k, specific heat c, and mass density ρ.
Specify internal heat sources Q within the geometry.
Specify temperatures on the boundaries or heat fluxes through the boundaries. For heat flux through the boundary ht(T−T_{∞}), specify the formation temperature T_{∞} and the heat transfer coefficient htc.
Set an initial temperature or initial guess.
Solve and plot results, such as the resulting temperatures, temperature gradients, heat fluxes, and heat rates.
Approximate dynamic characteristics of the thermal model of the wellbore and formation by using reduced order modeling (ROM).
   Referring to FIG. 5, Properties module 462 may include finite element mesh using “FEMesh object” (box 463); select and apply heat source within the domain or subdomain (box 464); select type of thermal analysis using “transient-axisymmetric” (box 465); boundary conditions applied to the geometry using “Edge”, “HeatFlux”, “ConvectionCoefficient”, and “AmbientTemperature” (box 466); geometry description using “DiscreteGeometry” 2D/3D models (box 467); select initial temperatures or guess (box 468); assign material properties within the domain using “ThermalConductivity”, “Mass Density”, and “SpecificHeat”, and “Face” (box 469). Solver Results module 470 may include interpolate temperature in a thermal result at arbitrary spatial locations (box 471); “thermalModal”, “DecayRange”, performs an eigen decomposition of a linear thermal model for all modes in the decay range (box 472); “thermalTransient”, “tlist” returns the solution to the transient thermal model at the times specified in tlist (box 473); evaluate integrated heat flow rate normal to specified boundary (box 474); evaluate heat flux of a thermal solution at nodal or arbitrary spatial locations (box 475); and evaluate temperature gradient of a thermal solution at arbitrary spatial locations (box 476).

### Modeling Hydrothermal Reactions

### Feed Biomass Slurry Characteristics and Processing Rates

In certain modeling methods of the present disclosure the biomass is prepared to achieve consistent physical and chemical properties such that it can be easily pumped using simple centrifugal pumps at low pressures. One example of typical properties includes those shown in Table 9 for an HTL process:

TABLE 9
Typical Biomass Properties

| Biomass | | | | Recycle Water | | Biomass Slurry as | | |
|---|---|---|---|---|---|---|---|---|
| as Received | | 125 | t/day | Added | | Prepared to HTL | | |
| Biomass % | 35 | 43.8 | t/day | | | 20 | 43.8 | t/day |
| (dry) | | | | | | | | |
| Water % | 58 | 72.5 | t/day | 90 | t/day | 76 | 162.5 | t/day |
| Inert Material | 7 | 8.8 | t/day | | | 4 | 8.8 | t/day |
| (assume ash | | | | | | | | |
| content) | | | | | | | | |

| | | |
|---|---|---|
| Processing Rate | 215 | t/day |
| Viscosity | 10-100 | cP |
| Particle Size Distribution | <1 | mm |

The prepared (as modeled) biomass slurry is pumped at low pressures (for example, less than 100 psi, or less than 75 psi, or less than 50 psi) into a deep well to generate hydrostatic pressure to depths of about 2,380 m (7,800 ft). At these depths, the hydrostatic pressure of the slurry reaches about 3,000 psi which is the target pressure for HTL. In practice, the depths could range from about 1,566 m (4,921 ft) to about 2,600 m (8,530 ft) which would generate a hydrostatic pressure of ranging from about 134 bar (1,961 psi) to about 224 bar (3,257 psi) depending upon the density of the slurry, as shown in Table 10:

TABLE 10
Typical Flow Rate and Density of Feed Biomass Slurries

| | | |
|---|---|---|
| Mass Flow Rate | 8,958 | kg/hr. |
| Density | 1.14 | kg/L |
| Volume Flow Rate | 188 | m³/day |
| | 7.84 | m³/hr. |
| | 130.7 | L/min |
| | 34.5 | gpm |

Referring again to embodiment 400 as illustrated in FIG. 9, biomass slurry 5 enters inner tubing 32 at the top of the well 44 at the surface and flows to the bottom of inner tubing 32 and product fluid 7 returns to the surface in annulus 38. Inner tubing 32 contains an electric resistance heating cable (34, 36) to raise feed biomass slurry 5 temperature to the target HTL temperature.

### Modeling Slurry Preparation

Biomass has a wide range of liquid and solid material types, content and particle size. In certain embodiments, before the biomass can be processed, it must be mechanically and chemically prepared to make a homogenous slurry suitable for pumping into a wellbore. Values for mechanical attrition and chemical additives can be input parameters in certain modeling methods of the present disclosure.

### Modeling Mechanical Preparation of Feed Slurry

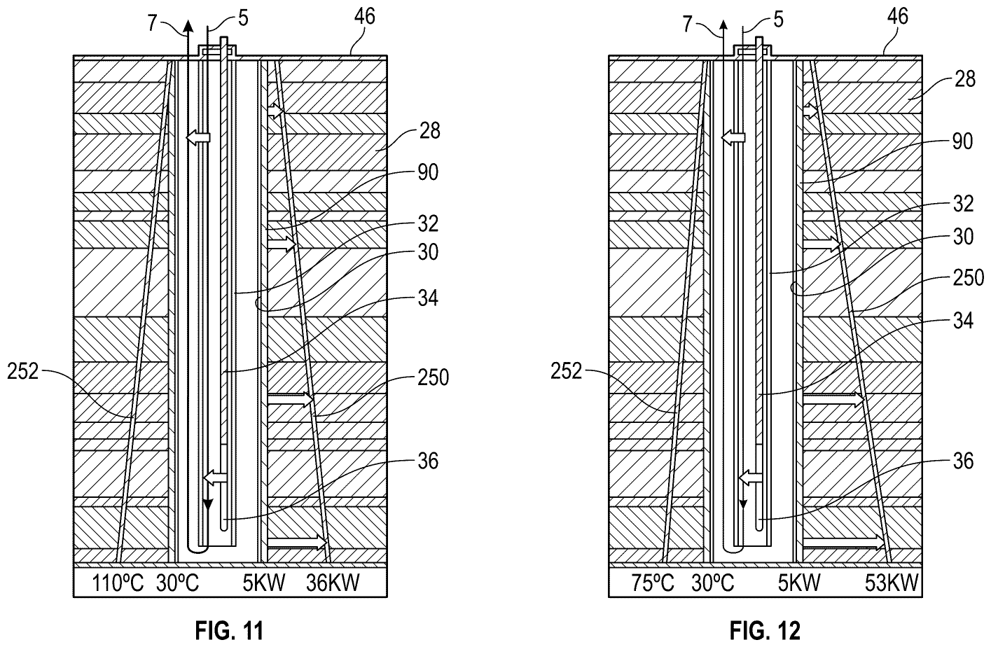

In certain modeling methods of the present disclosure, biomass may be modeled to have a wide particle size distribution and processed in mechanical equipment that may be modeled to increase surface area to promote HTL or HTC chemical reactions, allow it to pass through narrow piping and pump's rotor/stator housing, and reduce settling in the biomass slurry. In certain methods of the present disclosure, this may be accomplished using a series of equipment models for reducing biomass size as follows, referring to embodiment 500 illustrated schematically in FIG. 11:
Chipper—can handle larger biomass such as branches and pieces of wood and break them down into smaller chips. This is typically done on location at the source of the biomass (as indicated by the dashed line box in FIG. 11);
Shredder—similar to a chipper but can handle wet biomass also breaking down into smaller pieces. For model example: WEIMA WLK 1000, 125 rpm, 37 kW;
Re-shredder—material is then processed through a re-shredder to achieve <10 mm granulate which is then followed by a hammermill;
Hammermill—also known as a pulverizer, works on the principle of impact grinding. A hammermill consists of a rotor with impact hammers and external housing where material passes through the housing. For example: Scanhugger EU 4000 Hammermill with the main motor: 45-75 kW and capacity of 3000-4200 kg/h.

Multiple passes may be modeled to achieve the target particle size. Wet material may also be passed through a hammermill. Alternatively, a hardened pump erosion resistant impeller and housing referred to as a grinding pump, may be modeled depending upon the feed material size and type. A grinding pump is suitable when the particle size is <5 mm in a slurry. A hammermill and a grinding pump can be modeled in combination.

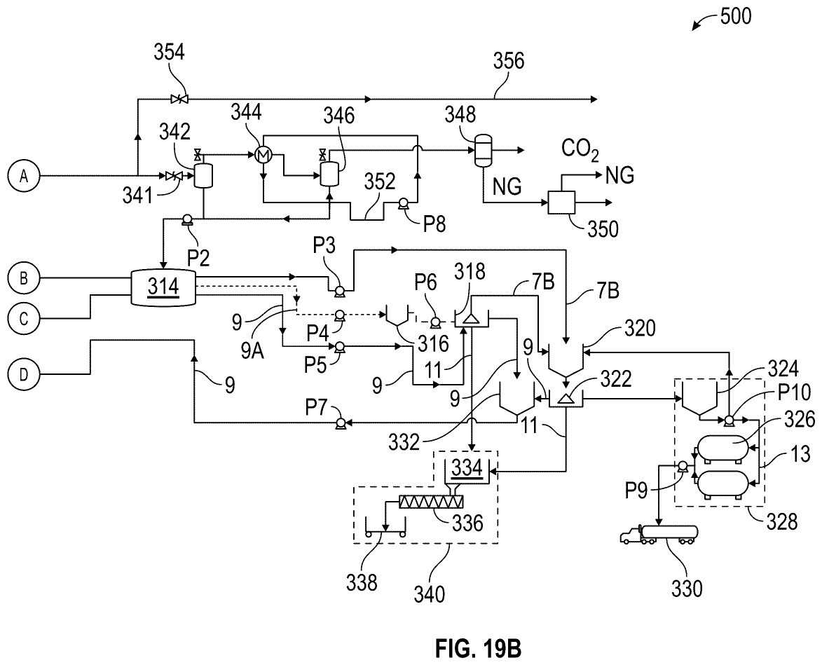

One embodiment that may be modeled is illustrated in FIGS. 19A and 19B, where one or more tank trucks 70 may deliver biomass to a receiving pit 71 (about 500 m³), from which a tractor 72 or other equipment may be employed to load the biomass onto a particle sizer and metal screener 73. Any metal is rejected into a trash bin 74. The main biomass stream is then routed to an agitated preparation tank 75 (about 10³ m) to which make up water is added via tanks 76A and 76B (about 50 m³ each). A grinder pump 82 is used to achieve the target particle size, a slurry loop is used with a circulating pump 77 feeding a hammermill 79 to pass the slurry over a vibrating shaker 80 with the target particle screen of 1 mm which rejects the oversize particles and directs the oversized material to further grinding through hammer mill 79 and/or grinder pump 82. The regrind slurry is passed over the vibrating shaker in a loop. The material passing through the screen on vibrating shaker 80 is ready for further feed slurry preparation and fed to staging tank 78 (about 10 m³). In practice, the particle size of the biomass slurry to be fed into the well reactors may range from about 0.1 mm to about 20 mm, or from about 0.25 mm to about 10 mm.

### Modeling Chemical Preparation of Feed Slurry

In certain embodiments, the staging tank 78 (or feed prep tank) can also be modeled to receive various chemicals to assist with the process such as corrosion inhibitors, cleaning chemicals such as surfactants, pH adjustment chemicals, heterogeneous and non-heterogeneous catalysts, and temperature resistant rheological additives such as bentonite.

The relatively high solids content in the feed slurry material are prone to settling and high risk of plugging the wellbore with solids when circulation is temporarily stopped. To avoid this risk, from about 0.1 to about 5 wt. percent (based on weight of feed biomass slurry) of a thermally resistant viscosifier capable of operating at 300° C. may be input into models of the present disclosure to reduce the settling rate of solids. In certain embodiments, the viscosifier generates a non-Newtonian slurry that is thixotropic, exhibiting a stable form at rest but becoming fluid when agitated to reduce solids settling rate; this is called “shear thinning ” This fluid flow behavior also reduces high friction losses when flowing thus resulting in lower pump pressures and low Reynolds numbers which negatively impact heat transfer coefficients. High heat transfer coefficients are important to reduce the requirement for high tube surface area for heat exchange between the inner tubing 32 and product fluid flowing in annulus 38. One such viscosifier is bentonite which after hydration, the bentonite particles expand 10-20 times their original volume. Bentonite is a mixture of various clay minerals that consists of from about 60 to about 80 percent montmorillonite. Further accompanying minerals can include quartz, mica, feldspar, pyrite or also calcite.

Fluids containing clays such as bentonite exhibit a pronounced thixotropic behavior. Thixotropic materials are fluids containing some form of structure as a result of formation of flocs or aggregates between suspended particles or moieties. In clay suspensions the formation of structure is promoted by increased encounter between suspended particles, which can result from Brownian motion of the particles or from the velocity gradient when the bulk of the material is sheared. Tehrani, A., “Thixotropy in Water-Based Drilling Fluids”, M-I SWACO Research and Technology Centre, Aberdeen, United Kingdom. Annual Transactions of the Nordic Rheology Society, Vol. 16, 2008. Fluids may be characterized as non-Newtonian plastic; Bingham plastic; non-Newtonian pseudoplastic (shear-thinning, n<1); Newtonian material, n=1; and non-Newtonian, dilatant (shear-thickening, n>1), where “n” is a parameter known as the “flow index” in the three-parameter rheological model for fluids known as Herschel-Bulkley fluids.

In certain modeling embodiments, bentonite can be modeled to be prehydrated with fresh water into a fluid and mixed with the feed biomass slurry. Alternatively, bentonite can be added directly to the feed biomass slurry while ensuring that the water phase in the feed biomass slurry is within pH and hardness range to fully hydrate. In addition to modifying the rheological properties, bentonite has distinctive features such as a versatile metal free catalyst that can be used to promote various chemical reactions. Bentonite clays have a variable net negative charge, which is balanced by Na, Ca, Mg and, or H adsorbed externally on the interlamellar surfaces. The structure, chemical composition, exchangeable ion type and small crystal size of the clay are responsible for several unique properties, including a large chemically active surface area, a high cation exchange capacity and interlamellar surfaces having unusual hydration characteristics as previously mentioned. Odom, I. E., “Smectite clay minerals: properties and uses”, American Colloid Company, Phil Trans. R. Soc. Land. A311, 391-409 (1984). Catalysts can potentially reduce reaction temperatures and increase biocrude yields.

### Modeling Water and Sludge Recycling

The HTL product fluid 7 exiting the annulus of the wellbore of deep well reactors contain gas and liquid phases. Gas/liquid separators may be modeled, while an oil/water/solids separator that separates the mostly liquid phase comprising water, biocrude, and small amount of solids into three primary streams may be modeled: biocrude oil, water, and solids, each containing varying degrees of the other stream. In certain embodiments, one or more of these streams may be polished via centrifuge modeled to generate relatively contaminant free streams, such as dewatered, polished biocrude stream.

The water separated from the process can be modeled to be recycled and mixed directly with the feed material as part of the feed biomass slurry preparation. The separated solids are the sludge from the settled solids layer that contains unreacted biomass solids, carbonized biomass and other inert feed solids residuals from oil/water/solids separator. The solids separated from the process can be used for land application or sold as a beneficial reuse as an inert carbon rich product. Similar to the separated water, this sludge may be modeled to be returned and mixed with the feed biomass slurry to further process the unreacted or partially reacted biomass to increase the biocrude yield. Other benefits of returning the sludge to the feed is that the stream does not require any dewatering and all heat energy in the sludge is conserved. The fate of the chemical additives will depend upon numerous factors, some of which are not known at this time. However, it is expected that some of the dissolved inorganic chemicals will oxidize and precipitate, be removed with the sludge or stay in the circulating loop. For organic chemicals, it is likely that at the operating temperatures, they will be decomposed or removed with the sludge or stay in the circulating loop.

### Modeling Deep Well Reactor Construction

In certain method of modeling embodiments, the well is constructed using an existing oil and gas production well, so that terminology may be used in modeling such a system and method. The well may be modeled to include production tubing serving as the inner tubing, and a production casing serving as an outer tubing that is bonded to the subsurface formation using cement, forming a well annulus. Multiple inner tubes could be used. “Casing” in these embodiments may include a conductor casing, surface casing, intermediate casing, and production casing. Drilling mud (also referred to herein as drilling fluid) may be modeled as positioned between the upper portions of the production casing and the formation, and between the other casings. The inner tubing length is selectively sized (or modified as described in other embodiments to achieve the selected length) to achieve the desired hydrostatic pressure. The inner tubing length is typically about 2,380 m. This type of well construction is commonly used in the production of oil and gas.

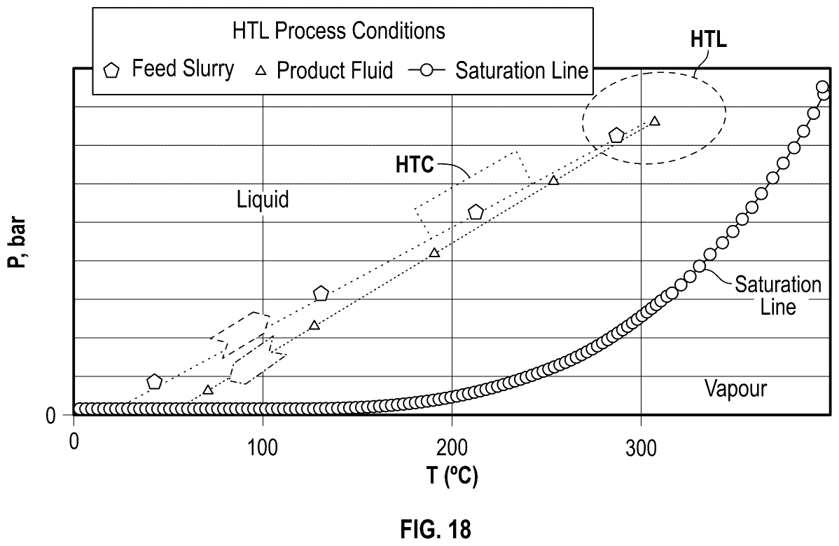

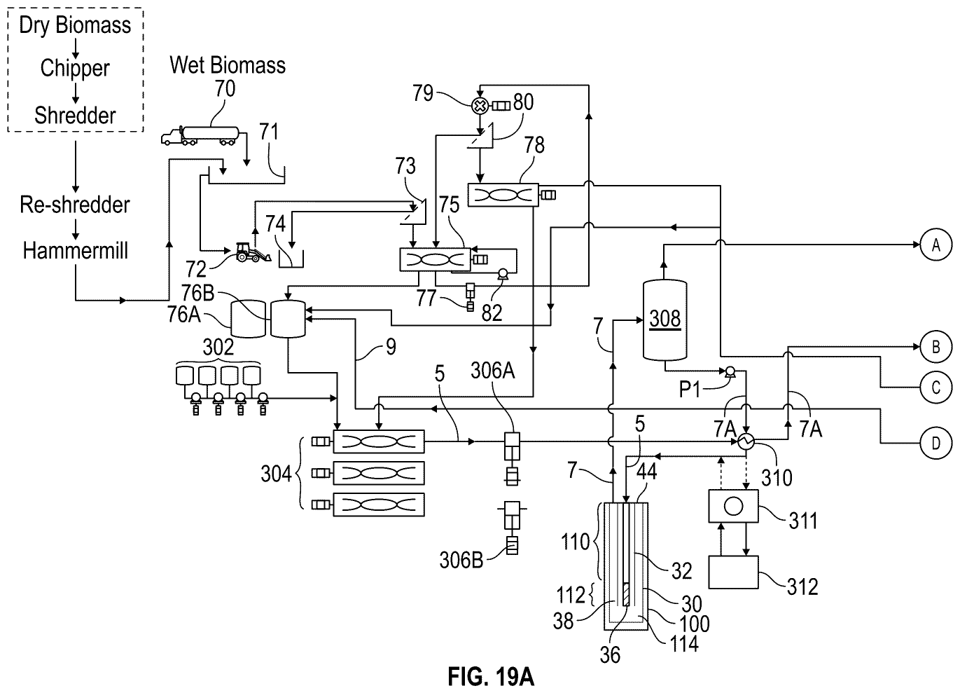

The graph of FIG. 18 illustrates schematically the temperature and pressure of the feed biomass slurry (upper dotted line) as it travels down the inner pipe of the wellbore while increasing temperature and depth/pressure. The return HTL product fluid (lower dotted line) exits the inner tube and travels to the surface as it decreases in temperature and pressure. Depth and pressure are directly correlated with hydrostatic pressure. The graph also shows the general pressure and temperature environments where HTL and HTC physical chemical reactions occur. As previously indicated, HTC reduces the biocrude yield so the time spent in the HTC favorable environments should be minimized as further explained herein.

Referring again to FIGS. 9 and 10, deep well HTL reactor embodiment 400 may be modeled as comprising two primary zones and a third zone:
Heat Transfer & Sub-surface Separation Zone (110);
HTL Reaction Zone (112); and
Return (product) fluid plenum (114).

In the Heat Transfer & Sub-surface Separation Zone 110, hot reacted HTL fluid that is heated at the bottom of the well travels to the surface in annulus 38. The HTL fluid in zone 110 preheats incoming feed slurry stream 5 in inner tubing 32 from ambient to approximately 280° C. Most of the heat is recovered via the transfer of thermal energy from the hot fluid in annulus 38 to incoming cold feed slurry 5 in inner tubing 32 while the remaining heat is lost to formation 28. In addition, the biocrude generated from the HTL reactions coalesce and separate from water in annulus 38 in zone 110. There is sufficient hydrostatic pressure to ensure that the water does not boil to steam.

In HTL Reaction Zone 112, the temperature of preheated feed slurry 5 flowing downward in inner tubing 32 is modeled to be boosted from about 280° C. to about 300° C. at the bottom portion of the well, 112. At this depth and in zones 112, 114, the feed biomass slurry is under sufficient pressure to ensure the fluid remains as a liquid and not turn to steam which is critical for HTL reactions to occur. The heat source comes from a submersed electrical resistance heater cable 36 inside inner tubing 32. A cement plug 116 is used to create the plenum zone 114. FIG. 10 illustrates schematically with arrows the heat loss to formation (118), heat transfer from hot HTL product fluid 7 to cold feed biomass slurry 5 (120), and heat transferred to feed biomass slurry 5 from electrical resistance heating cable 36 (122). The arrows show the direction of the heat transfer. Cable 36 heats the fluid in inner tubing 32 which then transfers the heat to the fluid in the annulus which then transfers some heat to the formation which is lost. This cross-section illustration in FIG. 10 changes with depth. It will essentially be the same if the cross-section is taken higher up the reactor but with no heating cable (only the power cable) and the heat source arrows will be in the opposite direction as identified in FIG. 10.

As the temperature of the feed biomass slurry 5 increases, sufficient pressure must be applied to ensure that feed biomass slurry 5 remains substantially (at least 95 percent, or at least 99 percent) in the liquid phase and above the liquid-gas saturation curve (FIG. 18) as the feed slurry is heated and cooled in the deep well reactor system for two reasons:
To ensure that steam is not generated that can impact fluid flow and heat transfer coefficient; and
To ensure energy is not wasted for the energy intensive step of water vaporization. The pressure in the system is generated by the hydrostatic pressure, as illustrated in the graph in FIG. 18 which illustrates the feed biomass slurry (upper straight dotted line) and return HTL fluid (lower straight dotted line) are not in proximity to the saturation line (curved dotted line) thereby eliminating the risk of steam generation.

### Modeling Deep Well HTL Reactor Design With Sensor Cable

While there is no standard well design given the numerous possible combinations of tubing lengths, tubing diameters, metallurgy, thickness, connectors, and the like, the following example provides insight into the process equipment and methods, operating parameters, features and limitations that determine deep well HTL reactor design models. (Refer to Table 11.)

TABLE 11
Well Construction Mechanics for HTL

| | | |
|---|---|---|
| Inner Tube (Production | 2,314 | m |
| Tubing) Length | | |
| Outer Tube (Production | 168.40 | mm |
| Casing) ID | | |
| Inner Tube OD | 73.15 | mm |
| Inner Tube ID | 57.51 | mm |
| Power & Heater Cable OD | 30 | mm |
| Sensor Cable | 4 | mm |
| Production Tubing Cross- | 0.0026 | m² |
| Sectional Area | | |
| Annulus Cross Sectional | 0.0180 | m² |
| Area | | |
| Velocity of fluid in AA | 0.84 | m/s |
| Production Tube | | |
| Velocity of Fluid in BB | 0.12 | m/s |
| Annulus | | |
| Volume in Inner Tubing | 6.26 | m³ |
| Net Volume in Annulus | 43.53 | m³ |

Since there is no advantage in higher pressures to promote HTL reactions, the length of inner tubing 32 should be kept to the minimum length to minimize heat losses to the environment, cost of power and heater cable (34, 36), reduce repairs/maintenance and well intervention costs. If greater residence time is required, the length of inner tubing 32 could be increased and/or increase the diameter of outer tubing (casing) 30. As illustrated schematically in our co-pending patent applications, a sensor cable may be provided, having connections to one or more temperature sensors (260° C. sensor), (300° C. sensor), and secured to collars using coupling cable clamps/protectors.

Most existing oil and gas production wells exceed the typical depth required for HTL and HTC reactions. Therefore, in certain embodiments using such wells in modeling, the well is modeled to be sealed from the unused bottom portion of the well. There are two primary methods of sealing a well at the bottom of the outer tubing that are commonly used in oil and gas well construction: cement plug and packer. These devices and methods are discussed in our co-pending applications in more detail, and may be modeled to inner create an upper plenum above the inner cement plug and a lower plenum below the inner cement plug to ensure:
sufficient space in the upper plenum for the fluid 5 to reverse flow towards the surface,
allow for the thermal expansion of inner tubing 32 (calculations indicate that the inner tube 32 will expand and grow in length approximately 2.7-4.0 m depending upon steel type)
provide separation that cools the wellbore fluid 5 between inner tubing 32 bottom and the seal if a non-cement plug or seal is used, and
prevent the flow of fluids or gases via lower plenum from the original oil and gas bearing formation.

### Modeling Inner and Outer Tubes Design Examples

Tubing suitable for use as inner tubing 32 useful in modeling the systems and methods of the present disclosure may be input to be corrosion resistant material, high thermal conductivity and low wall thickness. The wall thickness is determined primarily by structural requirements due to weight of pipe and joint connections and primarily for pressure differential across the pipe wall as the pressure is essentially the same. Inner tubing 32 is affixed to the wellhead at the surface which forces the thermal expansion of inner tubing 32 axially in the downward direction where a sufficient gap exists in the upper plenum between the bottom of inner tubing and plug 116.

Inner tubing 32 diameter is modeled in HTL models to provide relatively high velocity and turbulent flow regime to:
Increase heat transfer coefficient for the heat transfer from the hot product fluid 7 traveling up to the surface in annulus 38 to the cold biomass slurry 5 traveling to the bottom of inner tubing 32;
Minimize deposition and fouling of the inside wall of inner tubing 32;
Increase rate of depolymerization and decomposition of the wet slurry biomass into smaller compounds;
Minimize residence time of the feed biomass slurry 5 in inner tubing 32 until HTL reaction zone (112) is reached to less than about 45 min. This is important to minimize the time the feed slurry spends in the carbonization environment (temperatures ranging from about 180 to about 250° C.) which the feed biomass slurry must pass through to reach HTL temperature and pressure environments. Carbonization negatively impacts biocrude yields. The length of inner tubing 32 section where the carbonization environment is present is approximately 450 m, therefore at velocity of about 0.84 m/s the time spent is 8.9 minutes of the total 48 min or 20 percent.

Conversely, in annulus 38, outer tube 30 (casing) diameter is designed (modeled) in HTL models to provide low velocity and laminar flow regime to:
Increase residence time for HTL reactions to occur in HTL reaction zone 112;
Promote repolymerization of small compounds formed from the decomposition and depolymerization in inner tubing 32;
Increasing residence times decreases viscosity of the biocrude;
Promotes the coalescence of the hydrocarbons generated by HTL reactions.
Increases the separation of the hydrocarbons from water. (Refer to Tables 12 and 13 below)

TABLE 12
Flow Regime for HTL

| | Inner Tubing FIG. | Annulus FIG. 11B |
|---|---|---|
| | 11A Cross Section AA | Cross Section BB |
| Velocity (m/s) | 0.84 | 0.12 |
| Viscosity (cP) | 10 | 20 |
| Annulus Hydraulic | 0.0275 | 0.0913 |
| Diameter (m) | | |
| Rho (kg/m3) | 1.142 | 1000 |
| Mu (Pa-S) | 0.01 | 0.02 |
| Re | 2,637 | 551 |
| | Transient Turbulent | Laminar |

TABLE 13

| | Inner Tubing | Annulus FIG. | |
|---|---|---|---|
| | FIG. 11A, Cross | 11B, Cross | |
| | Section AA | Section BB | Total |
| Total Time in Well (min) | 47.9 | 333.1 | 381.0 |
| Residence Time in Upper | 4.4 | 30.4 | 34.8 |
| Plenum (min) | | | |

As explained further in our co-pending HTL patent applications, in certain embodiments to further decrease the time in the HTC environment, a section of inner tubing 32 operating at between about 180° C. to about 250° C. can be reduced in diameter from the reference 73 mm to 44 mm at depths of about 1300 to about 1800 m, or for a total length of about 500 m, and this may be a parameter used in certain models of well reactors in accordance with the present disclosure. The diameter reduction has the benefit of reducing the residence time of feed slurry 5 in HTC environment from about 10 to about 6 min, a reduction of about 40 percent. Methods to reduce inner tubing 32 effective diameter can be accomplished with smaller diameter section of inner tubing 32 such as smaller ID production tubing sections commonly found in 9.1 m sections and screwed together with a threaded collar or a metal insert with the selected ID which could be placed in sections or the entire length, about 500 m in inner tubing 32.

### Modeling Use of Mixing Device in Annulus

To improve mixing in the laminar flow regime in annulus 38 for HTL modeling, an apparatus and method to increase turbulence may be modeled. Generic static inline mixers are available in various geometries; however, these geometries are unsuitable for very long lengths and can be prone to fouling when solids are present. As such, an apparatus that is less prone to solids build up and bridging may be used in certain embodiments. This may be modeled by modifying an interconnect tube collar with a mixing collar sleeve attachment that is clamped to an existing collar to reduce annulus 38 diameter, or a modified collar design with a similar outer diameter, collectively referred to as a mixing collar. The reduced annular distance increases velocity and at the downstream end of mixing collar, flow is disrupted, and eddy currents are generated, thereby enhancing mass and energy transfer. More details of these devices are provided in our co-pending applications.

### Modeling Embodiments Using Coiled Tubing as Inner Tubing

In certain embodiments, inner tubing 32 can be a modeled to be a coiled tubing string such as supplied by Halliburton, Schlumberger, Weatherford, and the like, typically on a truck. Coiled tubing (CT) is a long, continuous length of pipe wound on a reel or spool. The pipe is straightened prior to pushing into a wellbore and rewound to coil the pipe back onto the transport and storage spool. Depending on the pipe diameter (1 in. to 4-1/2 in.) and the spool size, coiled tubing can range from 2,000 ft to 15,000 ft [610 to 4,570 m] or greater length. To deploy CT downhole, the CT operator spools CT off a reel, usually assisted by a crane, and leads it through a gooseneck, which directs the CT downward to an injector head, where the CT is straightened just before it enters the borehole at a wellhead. A stripper blowout preventer (BOP) is also provided and may be modeled. The portability of a coiled tubing unit allows the removal of the tubing from the well for inspection and maintenance, clean any deposition on the tubing wall and repairs and maintenance that can be spooled back onto the reel. A CT unit could be installed permanently and fully integrated with the wellhead. In certain embodiments, a lower pressure-rated wellhead could be employed, as explained more fully herein.

Material buildup on the exterior wall of inner tubing is expected. Less material is expected on the interior wall of the inner tubing 32 due to high velocity and low residence time. A cleaning system enclosed in a box with high pressure water sprayer nozzles around inner tubing with fluid collection, separation and return to high pressure pump loop can be utilized and modeled, as explained more fully in our co-pending applications. Surfactants, acids and caustic chemicals may also aid in the removal of any deposition. The tube continuously moves through cleaning system in these embodiments. Inputs to the model may include nozzle design, number of nozzles, nozzle flow rates, nozzle exit pressure, and nozzle positioning, which will vary from system to system, but certain embodiments may feature-two sets of four flat fan nozzles with fan angle ranging from about 25 to about 36 degrees spray positioned in a spiral staircase manner essentially covering the pipe twice (available from Lechler or the like), flow rates ranging from about 20 to about 40 L/min (about 5 to about 10 gpm) per nozzle, at nozzle exit pressures ranging from about 10 to about 20 bar (from about 145 to about 290 psi), the nozzles set back about 1 to about 1.5 times the pipe diameter, and positioned in a spiral around the pipe offset 90 degrees from each other and the same in the axial direction. Flow rates, exit pressures, and angle of attack from nozzle to nozzle may be the same or different.

In certain embodiments, the heater cable, sensor cable and sensors can be integrated into the coiled tubing where the coiled tubing is preassembled with the heater cable placed inside the coiled tubing prior to mobilizing on location. These embodiments would provide for greater assurance of proper heater cable placement and reduces risk of potential blockages in the inner tubing when on location.

### Modeling Multiple Feed Biomass Slurry Tubes

For maximum capital, footprint, startup and heat loss efficiency, in certain embodiments, multiple feed biomass slurry inner tubings 32 may be utilized within a single wellbore, each having its own heater cable 36. The wellbore geometry should be modeled such that the fluid velocities, residence times and flow regimes remain in the same range as outlined herein. Generally, this would involve a larger diameter outer tubing 30 to accommodate a larger flow through annulus 38. In these embodiments the flow to each inner tubing 32 would be controlled to be independent and monitored so as not to have reverse flow.

### Modeling Heat Source Method

Referring again to FIGS. 9 and 10, heating in the HTL reaction zone (112) is provided by heater cable 34 placed inside inner tubing 32. The downhole power and heating cable 34 consists of two sections: power transmission and heating. Heating cable specifications are provided in our co-pending applications, and these specifications may be input parameters for methods of modeling in accordance with the present disclosure. In addition, the length of the heater cable must be input as another parameter for modeling purposes. Length is determined by the watt density of the heater cable, typically ranging from about 0.8 to about 2.0 W/m, and the heating requirement. Higher heating power watt density is desirable as it will reduce the time to heat the formation resulting in a faster startup of feed biomass slurry. The details of power distribution design (control cabinet power, fuse cabinet, transformers, and the like) for the heater cables could be modeled as well, and details of those components are given in our co-pending applications.

### Advantages of Heat Transfer Modeling

One of the biggest advantages of modeling methods of the present disclosure is the ability to model transfer of heat without the addition of a high-pressure heat exchanger to the overall process, high pressure safety systems and instrumentation. The heat from the HTL and HTC product fluids moving to the surface in the annulus is efficiently and safely transferred to the cold feed biomass slurry moving through the inner tube via the inner tube wall. Efficient heat transfer between the inner and outer tubes is critical to minimize energy consumption and controlling high returning product fluid 7 temperatures.

Referring again to FIG. 9, feed biomass slurry enters the well in most embodiments at ambient temperature and low pressure, about 50 psi for example. The feed biomass slurry rapidly increases in temperature in inner tubing 32 at 18.1 and 18.7° C./min in heat transfer and sub-surface separation zone 110 and HTL reaction zone 112, respectively. This high rate of heat transfer is due to the high velocity in inner tubing 32. The temperature gradient in inner tubing is positive 0.08° C./m vs. negative gradient of 0.12° C./m in the annulus as heat is transferred to the feed biomass slurry in inner tubing 32. The difference in inner tubing and annulus is due to the temperature differential which is required for the heat transfer. The thermal energy from the exiting fluid can be further recovered by preheating the feed biomass slurry with commonly available high surface area plate frame heat exchangers or heat exchanger designs that can operate in the relatively low temperature and pressure environments at the surface. Alternatively, the separated water in the HTL product fluid 7 can be mixed directly with the feed biomass slurry as part of the makeup water to harness all the energy in the HTL product fluid 7. Separation equipment at surface will need to withstand the operating temperature of the outbound HTL product fluid 7.

### Modeling Heat Loss to Formation

Modeling transient heat loss to the formation is a geomechanical, thermal and fluid flow problem which can be conducted with finite and discrete elemental methods. Heat transfer and thermodynamic equations can be used to calculate the heat losses over time. Fundamentally, the thermal energy is transferred to the formation via the outer tube wall and cement bond interface between the outer tube and formation from the heated fluid with the heater cable as the source.

In order to model heat loss to the formation, several characteristics and parameter assumptions must be made including geological properties, wellbore construction, thickness and length of wellbore materials, thermal conductivity and specific heat of steel, concrete, drilling fluids and formation, surface areas and impacted formation volume, operating and formation temperature. Calculated results based on the assumptions described herein are illustrated schematically in FIG. 11. Calculations were conducted in equally spaced segments in the vertical direction. In modeling methods of the present disclosure the temperature inside the wellbore is assumed to be equal to the temperature of the outer tubing. This generates a temperature gradient with the reservoir temperature at a particular distance from the interface. It is generally understood that formation temperatures increase with depth at approximately 0.025° C./m but is location specific and dependent upon many geological factors and can be as high as 0.04° C./m. (SINTEF. “Drilling the world's hottest geothermal well”, ScienceDaily, 23 Oct. 2015).

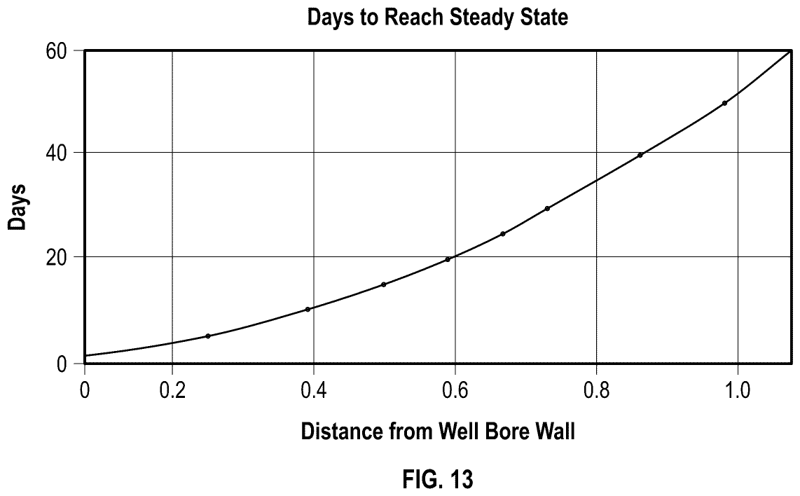

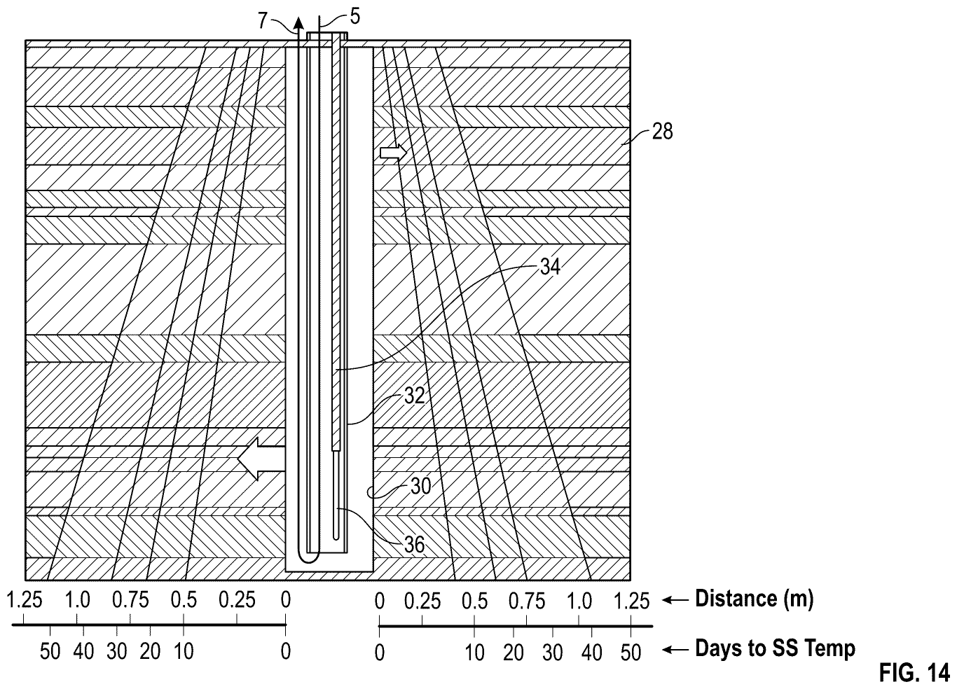

Overtime, as illustrated in FIG. 13, as heat is lost radially to the formation, the formation temperature will rise and exceed the natural formation temperature eventually reaching a steady state temperature at a particular distance. The time taken to reach the outer edge temperature at a particular distance was modeled and the results depicted in FIG. 14. This can be generally referred to as “soak time”. Line 250 in FIGS. 11 and 12 shows heat loss to formation 28 in kW, and line 252 in FIGS. 11 and 12 shows temperature of formation 28 of 110° C. and 75° C. respectively. FIGS. 11 and 12 illustrate the impact of higher formation temperatures resulting in lower heat losses to the formation.

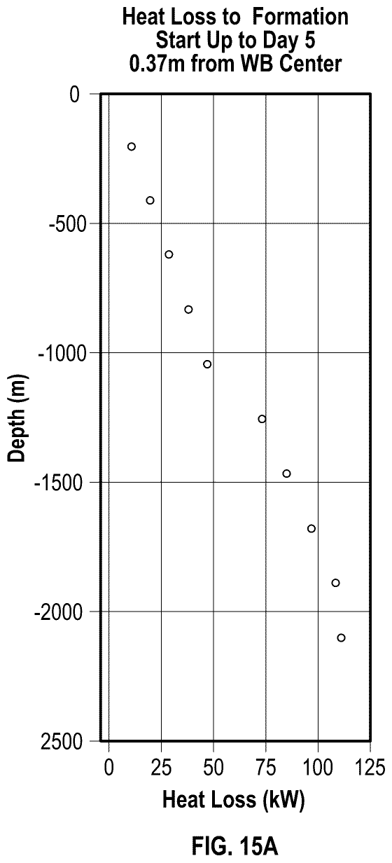

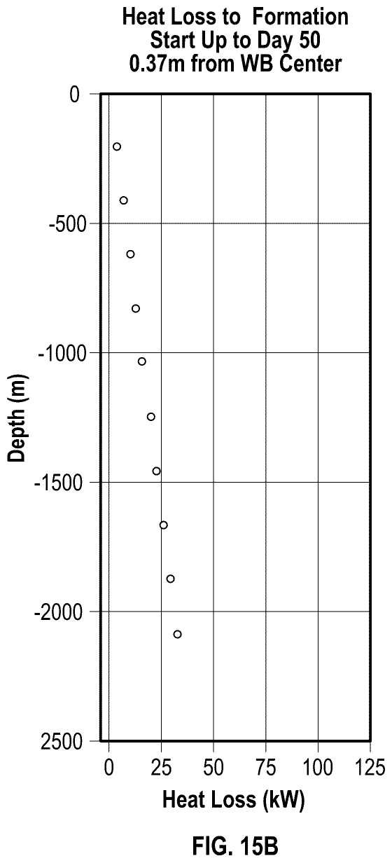

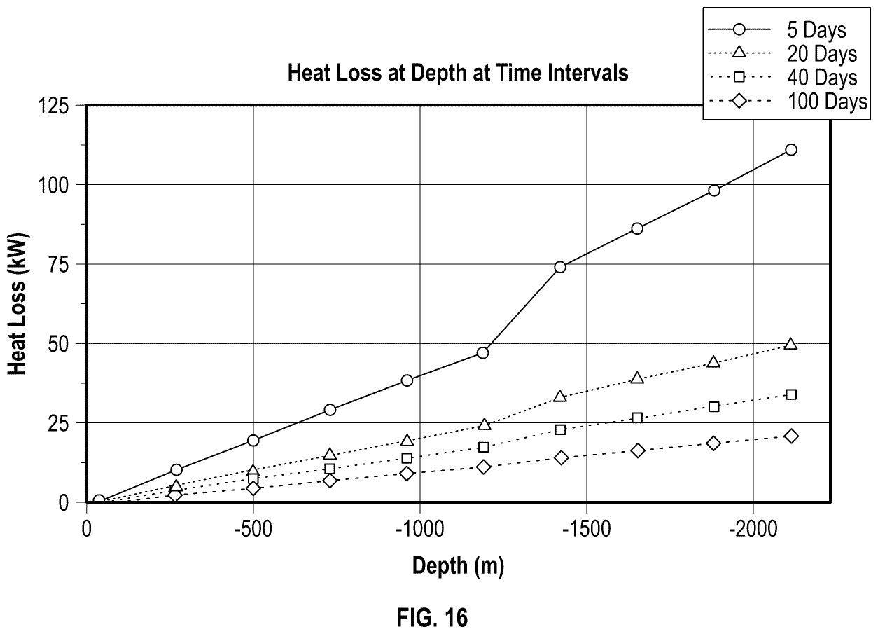

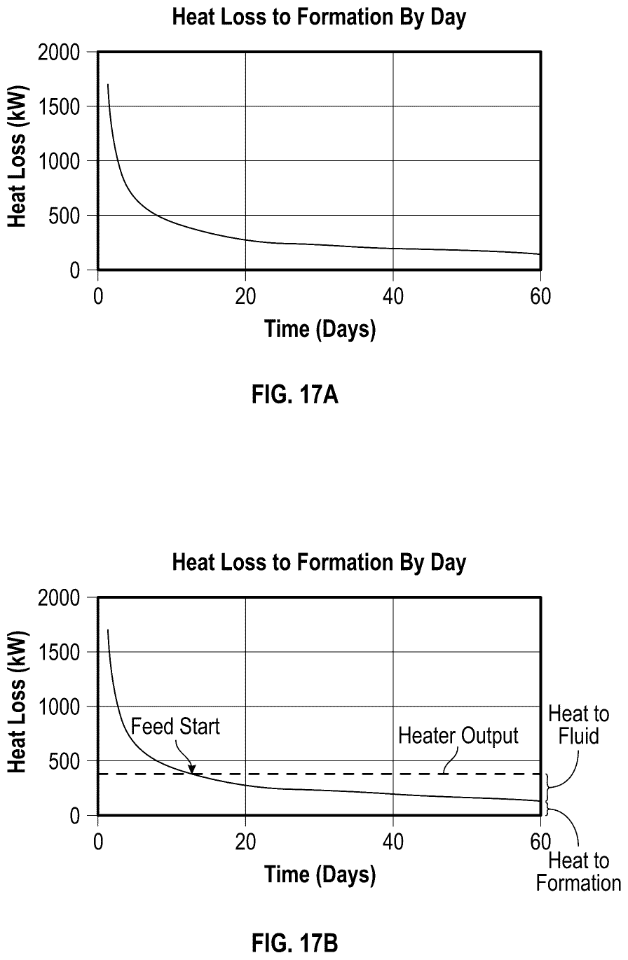

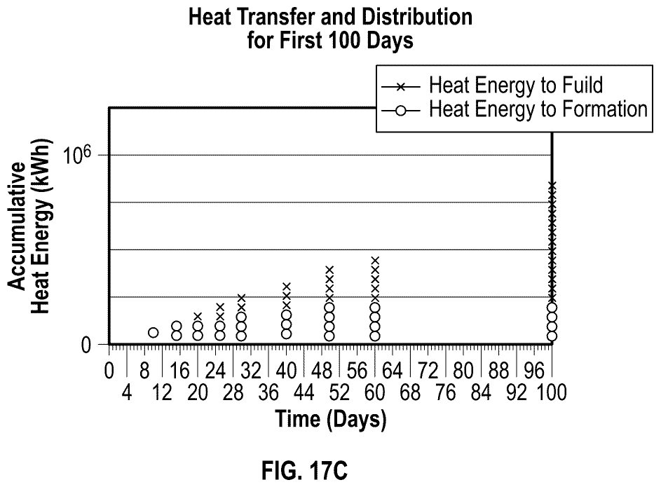

By way of two examples, FIGS. 15A and 15B illustrate the heat loss profile at two different times and at a fixed radial distance from center of the wellbore. The heat loss is significantly more at Day 5 vs Day 50 at all depths. The graph in FIG. 16 shows an alternate depiction of the heat loss over time and depth. Mathematically integrating the heat loss profile, the heat loss over time can be calculated as shown in FIGS. 17A and 17B.

Heat loss to the formation is greatest at the cold start of the process where the temperature gradient between the fluid 7 in the annulus and the formation 28 is the greatest. As illustrated in FIG. 17B, the heat loss to the formation 28 reduces over time as the formation around the wellbore increases in temperature, specifically the delta T associated at that depth which is variable with depth, i.e. heat loss is greater at the bottom of the wellbore vs surface. Initially, the majority of the heat is transferred to the formation as the starting fluid 5 (feed biomass slurry or a simple water starting fluid) is circulated through the wellbore. The starting fluid is circulated in and out of the wellbore until the formation reaches target temperature after which the feed biomass slurry can be fed into the deep well reactor. When the heat loss to the formation equals the heat output of the heaters (350 kW), then the net heat to the feed biomass slurry is initiated. As time passes, an increasing amount of heat is transferred to the feed biomass slurry while heat loss to the formation is decreasing. Practically, this means the feed biomass slurry processing rate increases and cost of energy decreases over time.

Heat loss to the formation is the greatest source of energy requirement for the systems and methods of the present disclosure. The graph in FIG. 17C shows the accumulated thermal energy and the distribution to the fluid 5 and formation. Once the formation is heated sufficiently, i.e. at about Day 15, a greater portion of the heat added to the system is distributed to the fluid. For example, at Day 20 only 16 percent of the energy is transferred to the fluid versus 64 percent at Day 100. This trend continues slowly but indefinitely, i.e. 91 percent after four years.

Heat loss profiles at different times and at a fixed radial distance from center of the wellbore may be generated. Mathematically integrating the heat loss profile, the heat loss over time can be calculated. Heat loss to the formation is greatest at the cold start of an HTL or HTC process in accordance with the present disclosure, where the temperature gradient between the fluid 7 in the annulus and the formation 28 is the greatest. The heat loss to the formation 28 reduces over time as the formation around the wellbore increases in temperature, specifically the delta T associated at that depth which is variable with depth, i.e. heat loss is greater at the bottom of the wellbore vs surface. Initially, the majority of the heat is transferred to the formation as the starting fluid 5 (feed biomass slurry or a simple water starting fluid) is circulated through the wellbore. The starting fluid is circulated in and out of the wellbore until the formation reaches target temperature after which the feed biomass slurry can be fed into the deep well reactor. When the heat loss to the formation equals the heat output of the heaters (350 kW), then the net heat to the feed biomass slurry is initiated. As time passes, an increasing amount of heat is transferred to the feed biomass slurry while heat loss to the formation is decreasing. Practically, this means the feed biomass slurry processing rate increases and cost of energy decreases over time.

### Modeling Wellbore Heat Loss Reduction Methods

In certain embodiments, steps can be taken to minimize wellbore heat losses through wellbore design but cannot be eliminated. The following list summarizes methods to minimize losses:
insulating cement,
drilling fluid selection, and
placement of cement.

### Insulating Cement

Our co-pending applications illustrate schematically use of thermal resistant insulating cement at the time of well construction to reduce heat losses. A cement float collar and cement guide shoe may be used with a cementing head and cementing manifold to inject insulating cement (for example comprising perlite). Bonding of insulating cement to the casing, and bonding of insulating cement to the formation may be modeled. Drilling fluid is allowed to permeate and flow between the formation and the insulting cement.

Cement has a wide range of thermal conductivity 0.62-3.3 W/mK depending upon temperature, moisture condition and types of coarse aggregate. For the purposes of modeling, 1.7 W/mK was used. Significant improvements in insulating properties can be made with the addition of fly ash (Shahedan, et al., “Thermal Insulation Properties of Insulated Concrete”, Revista de Chimie. 70. 10.37358/RC.19.8.7480 (2019)); use of foamed thermal resistant cement; or the addition of perlite to the cement. Perlite is an amorphous volcanic glass and thermal conductivity as low as 0.15 W/mK is possible. In particular, foamed thermal resistant cement may withstand stresses and loads that occur in well construction during the curing, pressure test, completion, production, and injection phases of its life and provide zonal isolation during the life of the well. Petty et al., “Life Cycle Modeling of Wellbore Cement Systems Used for Enhanced Geothermal System Development”, Proceedings 28th Workshop on Geothermal Reservoir Engineering Stanford University, Stanford, California, Jan. 27-29, 2003. The density of cement is 1.96 kg/L and was reduced to 1.08 kg/L with 20% foam cement, a 45 percent reduction. In addition, the thermal conductivity of the 20 percent foam cement was reduced by 65 percent. Maddi, “Smart Foam Cement Characterization for Real Time Monitoring of Ultra-Deepwater Oil Well Cementing Applications” (2016). The overall impact of a 65 percent reduction in thermal conductivity of cement on the entire wellbore results in an initial reduction of 4 percent in heat loss based on the example wellbore.

### Selecting and Modeling Drilling Fluid

As explained in our co-pending applications, during drilling and well construction, some drilling fluid permeates into the formation between cement and formation, and some drilling fluid remains behind the most outer casing and formation by design, typically between 1 mm-50 mm respectively. Intuitively using a lower thermal conductivity drilling fluid when drilling makes good sense because the thermal conductivity of generic water-based fluid is around 0.575 Wm·k (Hong et al., “Influence of MoS₂ Nanosheet Size on Performance of Drilling Mud”) and that of generic oil-based fluid is around 0.275 Wm·k (Fazelabdolabadi et al., “Thermal and rheological properties improvement of drilling fluids using functionalized carbon nanotubes”). Alternatively, a well can be drilled using air drilling methods in formations where there is no influx of water or hydrocarbon liquids. Compressed air at high flow rates and moderate pressures are used to circulate through the well bore. Air drilling eliminates the use of liquids entirely thereby inherently generating a porous and insulating layer between the outer casing and formation and the cement and formation. Mist and foam drilling can also provide similar benefits as they use limited amounts of water.

### Modeling Placement of Cement

The placement of cement between the casing (outer tube) and borehole may be modeled to ensure wellbore security, support casing, corrosion protection, isolating formation fluids and pressure containment. At intermediate depths, typical placement of cement is not taken to the surface. Where possible, the depth of cement should be kept to a minimum due to the thermal conductivity of cement at 1.7 W/mK vs drilling fluid at 0.572 W/mK. Drilling fluid provides better insulating properties than cement. In addition, water based drilling fluid will evaporate overtime at lower depths where temperatures exceed 100° C. thereby leaving more void space and improving thermal insulating properties. In alternative modeling embodiments, drilling fluid behind the casing can be displaced entirely with insulating cement (IC) along with non-insulating cement (NIC) used for securing the casing. This provides the benefit of structural integrity of cement and improved reduction in heat losses to the formation based on 0.572 W/mK for drilling fluid vs 0.15 W/mK for insulating cement as previously described.

### Modeling Geothermal Energy Contribution

One might believe that geothermal energy could be applied as a CO₂-free and natural source of heat, however there is a practical limitation to the access to geothermal energy. The temperatures at which the HTL well reactors operate in accordance with the present disclosure are well beyond any current geothermal wells which are typically less than 150° C. At deeper levels, drilling operations and materials integrity are faced with major challenges. Steel becomes brittle, and materials such as plastics and electronics either fail or start to melt. Normally, wellbore tool electronics only function for a short time at temperatures greater than 200° C. These problems must be resolved if the extraction of high-temperature geothermal heat is to become a going concern. However, geothermal energy can still play an important role in certain embodiments in minimize energy requirements by reducing heat loss to the formation by reducing the delta T between the fluid in the annulus and the formation. Smaller the delta T, lower the heat loss as previously discussed.

### Modeling of Process Flow Diagrams & Operations

### Process Flow Diagrams

Referring to FIGS. 19A and 19B, while not necessary in all embodiments, embodiment 500 includes equipment at both surface and subsurface that are fully integrated. The HTL processes are modeled to take in biomass materials and output four products: biocrude, process water, process gas and sludge. The HTC processes are similar but output hydrochar rather than biocrude.

### Modeling Feed Receiving, Storage and Preparation Equipment

Receive, screening, and storing the feed biomass material as it is received may be modeled. In certain embodiments, feed materials are selected with various properties, and homogenization and viscosity adjustment may be modeled, as may solids content and water properties. Grinding of the feed solids for the target particle size may be modeled. The biomass slurry passes over a vibrating screen 73 to remove debris, oversize material, and metal. The reject material is collected in a roll off bin 74 and transferred to a landfill. The material passing through the screen enters the grinding system. The grinding system prepares the biomass slurry so that particles are reduced to less than 1 mm. The grinding system in embodiment 500 includes feed prep tank 75, grinder pump 82 having a hardened impeller and pump housing for attrition, classifying vibrating screen 80, and an oversize particle return and feed prep tank 75. The biomass slurry is received in the grinding system receiving tank(s) 71 from one or more trucks 70 (or via railroad or other transport mechanism) and pumped to the classifying vibrating screen 73. The grinder pump 82 includes a hardened impeller and pump housing designed for attrition of the biomass materials while pumping the biomass slurry to the classifying vibrating screen 73. The classifying vibrating screen 73 utilizes 1 mm screens to separate >1 mm for further attrition. The >1 mm reject material is returned to the grinding system receiving tank 71 and passes through grinding pump 82 in a continuous loop, while the <1 mm slurry is transferred by gravity to feed prep tank 75. In certain embodiments, the screen size could range from about 0.5 mm to about 10 mm. Modeling of dumping or pumping various wet biomass materials collected from sources into a receiving pit 71. Material is typically received in vacuum trucks 70, tankers, sealed roll off bins and other containers. A gantry crane (not illustrated) equipped with a clam shell bucket homogenizes the material into a homogenous mixture/slurry in pit 71. Recovered and separated water 9 from the downstream separation process may be modeled to be routed to makeup water tank(s) 76A and 76B and mixed with the biomass mixture in one or more feed tanks 304 to make the biomass slurry 5. Selection of one or more additives to be mixed into the biomass slurry from tanks 302, such as catalysts, pH adjustment chemicals such as sodium hydroxide or sulfuric acid, chlorine, and the like, may be modeled, as well as the mixing facilities.

### Modeling of Feed Slurry Composition, Mixing and Pumping

Selection, addition, and mixing of chemicals into biomass slurry precursor may be modeled, for example, employing one or more chemical tanks 302. The preparation of HTL or HTC feed biomass slurry from the biomass slurry precursor and chemicals may be modeled, as well as pumping the feed biomass slurry to a feed preheater heat exchanger 310 to recover thermal energy from an HTL or HTC product fluid 7A from which light ends have been removed. Pumping (via one or more feed pumps 306A, 306B) the HTL or HTC feed biomass slurry to deep well reactor 100 may be modeled. Recovered water 9 can be modeled to be added to the ground feed slurry in feed tanks 304. The feed biomass slurry 5 is modeled to be prepared to meet flow and viscosity characteristics suitable for pumping as described in Table 3. Agitation of feed tanks 304 may be modeled, which could include modeling of circulating pumps with jets or standard shaft/impeller agitators to ensure solids remain suspended in the slurry. Feed tanks 304 can also be modeled to receive various chemicals 302 to assist with the process such as corrosion inhibitors, cleaning chemicals such as surfactants, pH adjustment chemicals such as sodium hydroxide, sulfuric acid, chlorine, and the like, heterogeneous and non-heterogeneous catalysts, and thermal resistant rheological additives such as bentonite. The biomass slurry feed pump 306A, 306B may be modeled as a vertical multistage centrifugal slurry pump capable of pumping up to 10,000 L/hr., 100 cP, 1.5 SG and 7 bar such as a Gol Pump model SBI 10-16. Biomass slurry 5 from feed tanks 304 is pumped at <100 psi pressure and ambient temperature into the feed preheater heat exchanger 310, which may be modeled as a plate frame heat exchanger or other design, where feed biomass slurry 5 is heated with return HTL product fluid 7A (from which light ends have been removed in two-phase separator 308) from annulus 38 of a modeled well reactor 100. HTL product fluid 7 comprises products from the hydrothermal liquefaction reactions of the biomass, typically biocrude, biochar, water, gasses, and inert materials at temperature less than about 70° C. and less than about 100 psi. The feed biomass slurry 5 is heated from ambient to about 20° C. less than the HTL product fluid temperature or approximately 50° C. in modeled feed preheater heat exchanger 310. Optionally, in certain embodiments, a coiled tubing unit 311 and high-pressure cleanout unit 312 may be modeled and employed, as indicated by dashed lined arrows downstream of preheater heat exchanger 310 and as discussed previously herein.

### Modeling of Deep Well Reactors

The purpose of modeling of Deep Well Reactors is to allow a user to select the feed biomass slurry 5 and evaluate the application of sufficient pressure, temperature and residence time for HTL or HTC reactions to occur, while in the case of HTL, minimizing hydrothermal carbonization reactions for the selected feed biomass slurry 5. After the conversion of the biomass slurry, the HTL or HTC product fluid and gas byproducts may be modeled to return to the surface for separation and recovery. The preheated feed biomass slurry 5 enters the deep well biomass conversion reactor 100 through the inner tubing 32 of the reactor about 2380 m (about 7800 ft.) in length (for HTL well reactors) that comprises two zones. As the feed biomass slurry 5 travels to the bottom of inner tubing 32, it gathers heat from HTL product fluid 7 in annulus 38 to about 280° C. to 2160 m, referred to herein as Zone 1, Heat Transfer & Sub-surface Separation (110). HTL product fluid 7 travels to the surface counter-currently to feed biomass slurry 5. Feed biomass slurry 5 is further modeled to be subjected to heat from the heater cable 36, raising the temperature from about 280° C. to the target of 300° C., referred to as Zone 2 HTL Reaction (112). In this example, the residence time of feed biomass slurry 5 in inner tubing 32 in Zone 1 and 2 may be modeled to be about 48 minutes and about 5 minutes, respectively, which times may vary depending on the feed biomass slurry characteristics, well reactor structure, and efficiency of the heater cable. The residence time in Zone 1 should preferably be as low as practical, ranging from about 20 to about 60 minutes. The residence time in Zone 2 should be such that the fluid temperature is raised to the target temperature in as short as time as possible which ranges from about 2 to about 8 minutes. The velocity of feed biomass slurry 5 in inner tubing 32 may range from about 0.6 to about 1.5 m/s, and velocity of HTL product fluid 7 in annulus 38 may range from about 0.10 to about 0.2 m/s. Feed biomass slurry 5 exits inner tubing 32 at about 2,380 m and enters return plenum 114 where the flow is thereafter channeled to annulus 38 where HTL product fluid 7 travels to the surface. HTL reactions occur in Zone 2 (112), both in inner tubing 32 and in annulus 38 at temperatures ranging from about 280° C. to about 300° C. and pressures ranging from about 180 to about 205 bar. In this example, the residence time of HTL product fluid 7 in annulus 38 in Zone 1 (110) and Zone 2 (112) are about 333 minutes and about 48 minutes, respectively, in embodiment 500. It will be understood that these tubing lengths, temperatures, and pressures will be less for HTC well reactors.

In most embodiments, while not necessary, before the feed slurry flow to the well reactor can be initiated the wellbore is heated to ensure that feed biomass slurry 5 will reach the target temperature, and this may be modeled. In these embodiments, initially, the temperature of the steel tubing/casing, concrete and adjacent drilling fluid is heated followed by the formation to a certain distance as described previously herein. This is generally referred to as the soak period which has been calculated to be approximately 15 days based on assumptions of well construction and formation characteristics used in the modeling. The heat may be modeled to be provided by circulating a heat soak fluid, for example, but not limited to inorganic fluids such as water, steam, nitrogen, air, synthetic air, and organic fluids, such as natural gas, light hydrocarbons, glycol solutions, and the like through inner tubing 32 and heated with the 350 kW heater cable 36. The heat soak fluid, if not already at temperature (such as when steam is used), is heated to about the same temperature as the feed biomass slurry. The heat soak fluid in annulus 38 heats outer steel tubing/casing 92, cement 90 and/or 272, drilling fluid 98, and formation 28. In the case of water used as the heat soak fluid, the same water is returned to inner tubing 32 inlet 44 and recirculated. After 15 days (or other modeled time period) of recirculating and heating, the feed biomass slurry can be initiated at a rate that matches the heat energy available which equals the heat generation from the heater cable less the heat loss to the formation as previously discussed. Heat loss to the formation is continuously decreasing over time and therefore the feed biomass slurry feed rate can be increased accordingly.

The heat soak period can be accelerated in the modeling methods by adding heat at the surface to the water or other heat soak fluid exiting annulus before returning to the inner tubing. The heating at the surface can be modeled to be performed by a traditional water heater, raising the temperature to below boiling point of approximately 90° C. while ensuring that the annulus water temperature does not exceed boiling temperature.

The modeling methods herein may account for CO₂ and some hydrocarbon gases formed in the practice of the systems and methods of the present disclosure, as described earlier. The product fluid may be modeled as a multiphase stream. These gases are in the liquid phase due to the hydrostatic pressure in the well bore, however as the flow of liquids travels to the surface, gaseous products separate from the liquid phase. The gas flow pattern is dependent upon volume, density, temperature, pressure, pipe geometry that determines the relative velocities of gas and liquid. The flow pattern starts as a single liquid phase flow transitioning to bubble flow somewhere in the wellbore annulus and eventually reaching annular flow regime as fluid nears the surface while gas velocities increase significantly. It is desirable to minimize gas velocity to improve heat transfer in the well bore between the counter fluid flows in the inner tubing(s) and annulus along with the external feed preheater 310 because gas is a poor conductor of heat. Also, relatively high volumes of gas require larger volume two phase separator (gas/liquid) vessels (308 in embodiment 500, FIG. 11). To minimize gas flow and velocity, back pressure on wellbore annulus exit may be modeled to be applied (via backpressure valve 341 in embodiment 500, FIG. 11) to minimize the specific density of the gas phase by adjusting backpressure valve (BPV) 341 downstream of two-phase separator 308.

### Modeling Gas-Liquid-Sludge Separation & Storage

The multiphase product fluid produced by the simulated well reactor and selected feed biomass slurry may be further modeled to be separated and/or treated for maximum recovery of valuable products and to minimize waste. The valuable products may be stored with non-biocrude products, recycled internally, or sold externally. The gas and liquid in annulus 38 exit the wellbore and are routed into one or more modeled two-phase separators (308) programmed to allow the liquid phase to settle under gravity and pumped via transfer pump P1 to preheater heat exchanger 310, and then to oil/water separator 314, while the gas phase from two phase separator 308 is transferred to a knock-out vessel 342. The liquid level in two-phase separator 308 is determined by regulating BPV 341 which also controls the flow of liquid to the oil/water/sludge separator (OWS), 314. The flow to OWS 314 can be accomplished with a knock-out vessel transfer pump P2 or the pressure in two-phase separator 308 via a valve (not illustrated in FIG. 11) working in concert with BPV 341.

Referring again to FIGS. 19A and 19B, OWS 314 may be modeled to separate the incoming fluid into three streams via gravity. One stream is a “raw” biocrude stream 7B, essentially floating oil in OWS 314 which is skimmed and transferred via recovered raw biocrude pump P3 to a recovered raw biocrude tank 320 and a polishing step to remove solids and water contaminants via biocrude polishing centrifuge including a disc stack 322 which further separates the recovered raw biocrude into (A) a saleable, in-spec biocrude (13) that is routed to tank 324, routed to sales tanks 326 via storage pump P10, and to offloading to trucks or other transport 330 via biocrude sale pump P9; (B) process water (9) which is routed from polishing centrifuge including a disc stack 322 to recovered water tank 332 for recycling via recovered water pump P7, and (C) sludge (11) which is routed to sludge receiver 334, sludge auger 336, and sludge storage bins 338 for disposal or sale (in certain embodiments sludge receiver 334, sludge processor 336, and sludge storage bins 338 may be in an off-site sludge management facility, 340). Polished biocrude tank 324, sales tanks 326, biocrude sales pump P9, and biocrude storage pump P10 may reside in an insulated facility, designed by the dashed area 328 in FIG. 11. The recovered and polished biocrude may be stored in sales tanks 326 at moderate temperatures (>50° C.) to ensure low viscosity for pumping and handling. The second stream produced by OWS 314 is a process water stream 9, pumped by recovered water pump P5 to recovered water tank 332.

A second stream produced by modeled OWS 314 is an emulsion (9a)—a floating middle layer composed of oil/water and fine solids emulsion which may build up overtime in OWS 314; in certain embodiments this emulsion layer is intermittently processed with an OWS centrifuge or tricanter 318 via an emulsion pump P4, tricanter feed pump P6, and tricanter feed tank 316. Tricanter 318 recovers more biocrude 7B, returns separated process water 9 to recovered water tank 332, and routs recovered sludge 11 to sludge receiver 334 for disposal or sale. Demulsifier chemicals may also be used in OWS 314 to aid in the separation process. A third stream produced by the OWS 314 is sludge (9). Sludge is a settled solids layer that contains unreacted biomass solids, carbonized biomass and other inert feed solids residuals and water slurry. This sludge is removed from OWS 314 via pump P4 and continuously processed with tricanter 318 or a separate decanter (not shown) for dewatering. The dewatered solids 11 are collected in sludge receiver 334 and managed as previously described. The separated water from Tricanter or decanter 318 is collected in recovered water tank 332 which is subsequently returned to Module 1, 76A and 76B. The sludge consisting mostly of biochar is analyzed and stored to determine value as a soil amendment for further reuse or disposal.

Referring again to FIGS. 19A and 19B, embodiment 500, the gas phase separated in modeled two-phase separator 308 from the raw biocrude stream 7 is processed to remove fine droplets of water and/or biocrude contaminants that are entrained in the gas phase. These contaminants may be modeled to be removed using one or more simulated knock out vessels 342, 346, which in certain embodiments may be modeled to include coalescing media, along with a heat exchanger (condenser) 344 that chills the gas stream using a chiller 352 and chiller circulation pump P8 to further remove any contaminants in the vapor phase. Any recovered liquid is returned to OWS 314 for recovery. The polished gas phase which contains mostly CO₂ but also some non-condensable gasses such as light hydrocarbons (C₁-C₄), and small quantities of H₂ and CO, is processed to separate CO₂ via commonly available methods such as membrane or pressure swing adsorption or amine solution (348), which may be modeled. The CO₂ free gas phase can then be used as fuel for internal processes as natural gas (NG), used in a natural gas generator 350, or sold as renewable natural gas (RNG). A rupture disc 354 allows venting to a vent line 356. In certain embodiments several rupture discs of various pressure ratings may be employed, and/or one or more pressure relief valves.

### Modeling Wellbore Flow Pattern in the Annulus

Our co-pending HTL applications include schematic illustrations of various phases of flow in the annulus in certain systems and methods of the present disclosure, and graphical representations of the flow regimes. Approximately 16 percent (dry ash free wt %) of the feedstock is converted into HTL off-gas comprising CO₂, CH₄, CO and H₂, primarily composed of 92 percent CO₂ and 8 percent C₁-C₅ gasses. “Conceptual Biorefinery Design and Research Targeted for 2022: Hydrothermal Liquefaction Processing of Wet Waste to Fuels”, December 2017, Prepared for the U.S. Department of Energy under Contract DE-AC05-76RL01830 Pacific Northwest National Laboratory. These gasses are in the liquid phase due to the hydrostatic pressure in the well bore, however as the flow of liquids travels to the surface, gaseous products separate from the liquid phase. The gas flow pattern is dependent upon volume, density, temperature, pressure, pipe geometry that determines the relative velocities of gas and liquid. Two-phase flow in vertical pipelines may be categorized into five different flow patterns: Bubble flow, Slug flow, Churn flow, Froth flow and Annular flow.

Modeling of the flow pattern in the wellbore was based on the reference feed biomass slurry flow rate and the gas generation as previously discussed. Table 14 shows the velocity of the gas and liquid phases. The flow pattern starts as a single liquid phase flow transitioning to bubble flow in the wellbore annulus and eventually reaching churn and froth flow in the last approximately 50 m before the gas and liquid exits the annulus.

TABLE 14
Modeling flow pattern in an HTL wellbore reactor

| | HTL Wellbore Gas and Liquid Flow with Annulus Back Pressure | | | | | | | | Without Back | |
|---|---|---|---|---|---|---|---|---|---|---|
| | Back pressure: | | | 50 psi | | | | Liq. | Pressure | |
| | Annulus | CO₂ | | Liq. | CO₂ | Liq. | CO₂ | Velocity | CO₂ | Liq. |
| Depth | Pressure | Density | CO₂ vol | Vol. | vol. | vol. | Velocity | BP | Velocity | Velocity |
| (m) | (psia) | (kg/L) | (m3/hr.) | (m3/hr.) | (%) | (%) | BP (m/s) | (m/s) | (m/s) | (m/s) |
| 0 | 65 | 9.0 | 32.5 | 7.8 | 81 | 19 | 2.6 | 0.6 | 16.7 | 1.5 |
| 66 | 133 | 16.3 | 17.9 | 7.8 | 70 | 30 | 0.9 | 0.4 | 1.9 | 0.5 |
| 132 | 216 | 24.8 | 11.8 | 7.8 | 60 | 40 | 0.5 | 0.3 | 0.7 | 0.4 |
| 198 | 298 | 33.0 | 8.8 | 7.8 | 53 | 47 | 0.3 | 0.3 | 0.4 | 0.3 |
| 264 | 381 | 40.8 | 7.1 | 7.8 | 48 | 52 | 0.2 | 0.2 | 0.3 | 0.2 |
| 331 | 464 | 48.3 | 6.0 | 7.8 | 44 | 56 | 0.2 | 0.2 | 0.2 | 0.2 |
| 397 | 547 | 55.5 | 5.3 | 7.8 | 40 | 60 | 0.1 | 0.2 | 0.2 | 0.2 |
| 463 | 629 | 62.4 | 4.7 | 7.8 | 37 | 63 | 0.1 | 0.2 | 0.1 | 0.2 |
| 529 | 712 | 69.1 | 4.2 | 7.8 | 35 | 65 | 0.1 | 0.2 | 0.1 | 0.2 |
| 595 | 795 | 75.4 | 3.9 | 7.8 | 33 | 67 | 0.1 | 0.2 | 0.1 | 0.2 |
| 661 | 878 | 81.6 | 3.6 | 7.8 | 31 | 69 | 0.1 | 0.2 | 0.1 | 0.2 |
| 727 | 960 | 87.5 | 3.3 | 7.8 | 30 | 70 | 0.1 | 0.2 | 0.1 | 0.2 |
| 793 | 1,043 | 93.2 | 3.1 | 7.8 | 29 | 71 | 0.1 | 0.2 | 0.1 | 0.2 |
| 859 | 1,126 | 98.7 | 3.0 | 7.8 | 27 | 73 | 0.1 | 0.2 | 0.1 | 0.2 |
| 925 | 1,209 | 103.9 | 2.8 | 7.8 | 26 | 74 | 0.1 | 0.2 | 0.1 | 0.2 |
| 992 | 1,292 | 109.1 | 2.7 | 7.8 | 25 | 75 | 0.1 | 0.2 | 0.1 | 0.2 |
| 1058 | 1,374 | 114.0 | 2.6 | 7.8 | 25 | 75 | 0.1 | 0.2 | 0.1 | 0.2 |
| 1124 | 1,457 | 118.8 | 2.5 | 7.8 | 24 | 76 | 0.0 | 0.2 | 0.1 | 0.2 |
| 1190 | 1,540 | 123.4 | 2.4 | 7.8 | 23 | 77 | 0.0 | 0.2 | 0.0 | 0.2 |
| 1256 | 1,623 | 127.8 | 2.3 | 7.8 | 23 | 77 | 0.0 | 0.2 | 0.0 | 0.2 |
| 1322 | 1,705 | 132.1 | 2.2 | 7.8 | 22 | 78 | 0.0 | 0.2 | 0.0 | 0.2 |
| 1388 | 1,788 | 136.3 | 2.1 | 7.8 | 21 | 79 | 0.0 | 0.2 | 0.0 | 0.2 |
| 1454 | 1,871 | 140.4 | 2.1 | 7.8 | 21 | 79 | 0.0 | 0.2 | 0.0 | 0.2 |
| 1520 | 1,954 | 144.3 | 2.0 | 7.8 | 20 | 80 | 0.0 | 0.2 | 0.0 | 0.2 |
| 1586 | 2,036 | 148.1 | 2.0 | 7.8 | 20 | 80 | 0.0 | 0.2 | 0.0 | 0.2 |
| 1653 | 2,119 | 151.8 | 1.9 | 7.8 | 20 | 80 | 0.0 | 0.2 | 0.0 | 0.2 |
| 1719 | 2,202 | 155.4 | 1.9 | 7.8 | 19 | 81 | 0.0 | 0.1 | 0.0 | 0.2 |
| 1785 | 2,285 | 158.9 | 1.8 | 7.8 | 19 | 81 | 0.0 | 0.1 | 0.0 | 0.1 |
| 1851 | 2,367 | 162.3 | 1.8 | 7.8 | 19 | 81 | 0.0 | 0.1 | 0.0 | 0.1 |
| 1917 | 2,450 | 165.6 | 1.8 | 7.8 | 18 | 82 | 0.0 | 0.1 | 0.0 | 0.1 |
| 1983 | 2,533 | 168.8 | 1.7 | 7.8 | 18 | 82 | 0.0 | 0.1 | 0.0 | 0.1 |
| 2049 | 2,616 | 171.9 | 1.7 | 7.8 | 18 | 82 | 0.0 | 0.1 | 0.0 | 0.1 |
| 2115 | 2,699 | 175.7 | 1.7 | 7.8 | 17 | 83 | 0.0 | 0.1 | 0.0 | 0.1 |
| 2181 | 2,781 | 180.3 | 1.6 | 7.8 | 17 | 83 | 0.0 | 0.1 | 0.0 | 0.1 |
| 2247 | 2,864 | 184.8 | 1.6 | 7.8 | 17 | 83 | 0.0 | 0.1 | 0.0 | 0.1 |
| 2314 | 2,947 | 189.2 | 1.5 | 7.8 | 16 | 84 | 0.0 | 0.1 | 0.0 | 0.1 |
| 2380 | 3,031 | 193.7 | 1.5 | 7.8 | 16 | 84 | 0.0 | 0.1 | 0.0 | 0.1 |

### Modeling Process Control Methods

To ensure efficient and safe transfer and separation of fluids, systems and methods of the present disclosure may be modeled to be controlled by one or more programmable logic controllers.

### Subsurface

Two methods are described to control the heater cable which in turn provides the desired set temperature and subsequently the heat transfer required for the HTL and HTC reactions. A first modeling method is to use a thermocouple (TC) with a cable to measure the temperature of the inner tubing wall. The temperature delta between target and measured will trigger the power controls to turn on/off the power to the heater cable to maintain temperature. In certain embodiments, three TCs may be used: TC1 is the primary TC to control the heater cable and is placed at the bottom of the inner tubing which will be used to ensure that the temperature of the feed biomass slurry has reached a set point of 300° C. A second thermocouple, TC2 is used to confirm the expected target temperature of 280° C. at the start of the heater section. Both TC1 and TC2 can be used jointly in certain embodiments to minimize response time and troubleshooting. A third thermocouple, TC3, is placed midway of the 600° C. rated power supply cable (lower portion, at greater depth) and is used to protect the 250° C. rated power supply cable (upper portion, extending from the 600° C. rated power supply cable to surface). If the TC3 temperature exceeds 250° C., essentially a High High trigger, then power to the heater cable can be stopped until high temperature subsides.

In other system and methods embodiments of the present disclosure, Distributed Temperature Sensing (DTS) systems may be modeled to measure downhole temperatures, where a single fiber optic cable can be run to the bottom of a well and the temperature can be monitored at several points along the wellbore, such as that supplied by Yokogawa (yokogawa.com). Yokogawa's DTSX200 is an integrated optical fiber sensing system designed to provide the most accurate distributed temperature measurements over long distances while reducing operating costs and increasing production. Measuring temperature across the entire wellbore can provide greater insight into the temperature profile of the fluid temperature thereby providing greater process control and troubleshooting. Distributed temperature sensing systems (DTS) are optoelectronic devices which measure temperatures by means of optical fibers functioning as linear sensors. Temperatures are recorded along the optical sensor cable, thus not at points, but as a continuous profile. A high accuracy of temperature determination is achieved over great distances. Typically the DTS systems can locate the temperature to a spatial resolution of 1 m with accuracy to within ±1° C. at a resolution of 0.01° C. Measurement distances of greater than 30 km can be monitored and some specialized systems can provide even tighter spatial resolutions.

The modeled systems and methods of the present disclosure are continuous and advantageously reduce or eliminate high pressure submersible pumps as the reactor pressure is generated using hydrostatic pressure.

### Modeling of Energy recovery

HTL is an energy-intensive process that operates at high temperature and pressure. With these high operating conditions, heat and energy recovery during cooling and depressurization of the product flow greatly affects the economic competitiveness of the process. (Ong et al.) Therefore, in modeling HTL systems and processes, the ability to model pre-heating of the feed biomass slurry with the hot HTL product fluid is a great advantage to the systems and methods of the present disclosure. This is accomplished through the use of simulated heat exchangers, however these heat exchangers are not commercially available. It is possible to custom design such a heat exchanger but it will be very expensive with exotic metallurgy and thickness, and requires a very large footprint. The 2019 State of Technology (Snowden-Swan et al.) showed that approximately 50 percent of the capital cost for a commercial HTL plant is from the heat exchangers used to preheat process slurry to the reactor temperature (350° C.). The high cost of the exchangers stems from the high viscosity of the biomass slurry feedstock, which leads to low Reynolds numbers and a large effective area requirement. The high operating pressure of the HTL process also leads to thick tube and shell walls. Snowden-Swan et al., “Wet Waste Hydrothermal Liquefaction and Biocrude Upgrading to Hydrocarbon Fuels: 2020 State of Technology”, March 2021, Pacific Northwest National Laboratory Richland, Washington. Overcoming the size, exotic metallurgy, construction of large wall thickness heat exchanger is required before HTL can be commercially successful. Systems and methods of the present disclosure solve this issue by use of wellbore inner tubing and outer tubing/casing along with insulating well construction design, all of which may be modeled, whereby the heat is transferred from the annulus to the feed biomass slurry which recovers a majority of the heat with the remaining going to heat losses to the formation. One interesting point about utilizing a deep well reactor is that the pressure differential across the production (“inner”) tubing(s) is minimal, thereby allowing a relatively thin wall thickness and metallurgy that is high in thermal conductivity, even aluminum could be used with adequate corrosion protection. The current calculations herein used a standard production tubing made of carbon steel with moderate thermal conductivity but using metals such aluminum, which would normally not be applied in oil and gas production due to the corrosive nature of the produced water/brines, has merit due to the unique aspects of the deep well HTL reactor and feed biomass slurries. The feed biomass slurries are generally fresh water based, low chlorides, low oxygen (also no oxidizers are added) and contain minimal dissolved solids and are near neutral pH (or can be made to a neutral pH without impacting the HTL reactions). Using aluminum and aluminum alloys provides the advantage of light weight, high strength is not required, low cost, can be extruded for unique surface geometries (such as axial fins for increased heat transfer surface) and made in long sections. Corrosion protection is important and can detrimental. For example, cannot touch the steel (carbon or stainless steel) as it will promote galvanic reaction and lead to corrosion which of course is the principle of anodic protection. The use of aluminum or aluminum alloys carries some risk that requires further investigation but has potential and plenty benefits.

In general, the production or inner tubing 32 may be modeled to have an outer diameter (OD) ranging from about 1 inch up to about 50 inches (2.5 cm to 127 cm), or from about 2 inches up to about 40 inches (5 cm to 102 cm), or from about 4 inches up to about 30 inches (10 cm to 76 cm), or from about 6 inches up to about 20 inches (15cm to 51 cm).

In certain modeling methods, the biocrude or hydrochar “produced” by the simulations may be compared with real-world biocrudes and hydrochars, and the models iteratively adjusted based thereon. As such, a discussion of biocrude properties (from Ramirez et al., “A Review of Hydrothermal Liquefaction Bio-Crude Properties and Prospects for Upgrading to Transportation Fuels”) is provided herein.

### Physical Properties

Viscosity—Viscosity is a measure of flow behavior of a fluid and an important quantity in many fluid flow calculations. For an organic compound its viscosity is related to its chemical structure. Boelhouwer, J. W. M., et al., “Viscosity data of organic liquids”, Appl. Sci. Res. 1951, 2, 249-268 concluded that straight chain hydrocarbons have higher viscosities than branched hydrocarbons, and alcohol or acid groups have more effect on viscosity compared to esters and ketones. Kinematic viscosity is more commonly used for fuels. High-viscosity fuel will not be well-atomized, leading to poor combustion, increased engine deposits, and higher energy requirements for fuel pumping. Moreover, higher fuel viscosity has been observed to increase carbon monoxide (CO) and UHC. In contrast, very low fuel viscosity leads to poor lubrication of fuel injection pumps, causing leaks and increased wear. This results in biodiesel standards having upper and lower limits in kinematic viscosity.

Density—In fuels, density is related to the energy content for a given volume. Since the engine injection system measures the fuel by volume, a higher density fuel will have a greater power output from combustion of a larger fuel mass. Density has also been correlated with increases in nitrogen oxides (NOx), particulate matter (PM), CO, and unburnt hydrocarbon (UHC) in emissions. The heating value and cetane number are also both related to density. In literature and in legislated standards, specific gravity is sometimes reported instead of density.

Heating Value—The fuel heating value is a common criterion for evaluating a liquefaction process. The heating value is a quantitative representation of the biocrude's energy content, which can be used to evaluate efficiency of converting feedstock to fuel. This quantity also gives the energy density of the fuel, which dictates how much energy is released with each volume of fuel injected into the combustion chamber. Heating value can be presented as a higher heating value (HHV) or a lower heating value (LHV). The HHV takes into account the heat of vaporization of water during combustion, while the LHV does not. In fuels, HHV has been correlated with chemical composition given by ultimate and proximate analyses. Recently, this approach has been applied for HTL biocrudes. Correlations state that heating value is directly proportional with the elemental composition, with carbon and hydrogen increasing heating value and oxygen and nitrogen having a negative effect. However, Ramirez notes that traditional correlations do not closely match experimental data for HTL biocrudes and so existing correlations should be modified. While HHV quantity is not regulated, it is prudent to produce biofuels with heating values similar to conventional fuels to ensure minimal modifications to engines, particularly in injection technology.

### Chemical Properties

Oxygen Content—Liquefaction biocrudes have significant oxygen content resulting from the depolymerization of biomass components (i.e., cellulose, hemicellulose and lignin). These oxygenated compounds take the form of organic acids, alcohols, ketones, aldehydes, sugars, furans, phenols, guaiacols, syringols, and other oxygenates. In crude oil refining, oxygen is removed to prevent poisoning of catalysts in the reforming process. Studies correlating oxygen content to fuel properties, engine operation and performance have been done on biodiesel. Lower CO emissions and PM have been observed for relatively highly oxygenated fuels such as biodiesel.

Nitrogen Content—Nitrogen in fuel may interact with degradation products and form solid deposits. Nitrogen content is not regulated by diesel or biodiesel standards, although in crude oil refining, nitrogen content is reduced through hydrotreatment to minimize catalyst deactivation and improve diesel stability. Biocrude from HTL of lignocellulosic materials usually has low levels of nitrogen with a maximum of 2 percent. Higher levels of nitrogen have been reported for biocrudes produced from garbage, wastewater sludge, and algae (up to 10 percent) due to the protein content of the feedstock.

Sulfur Content—The sulfur content of fuel is a regulated quantity as burning sulfur in fuel produces sulfur oxides and sulfate particles that contribute to PM emissions. Moreover, sulfur can cause increased cylinder wear and deposit formation. ASTM D975 and D6751 limits sulfur content in diesel and biodiesel, respectively, to 15 ppm. Lignocellulosic materials and algae have very minimal sulfur content. Biocrude has been produced with only 0.1-1.3 wt % sulfur. Biochar, on the other hand, has a higher sulfur content, which may mean reactions in liquefaction favor sulfur binding into compounds in the solid fraction.

Chemical Composition—Diesel is mainly composed of alkanes, alkenes and aromatics, while biodiesel is more oxygenated, comprised of fatty acid methyl/ethyl esters. HTL biocrude, on the other hand, is a complex mixture of oxygenated organic chemicals, aliphatics, sugars, oligomers, nitrogenous aliphatics, and nitrogenous aromatics. Table 15 shows the main chemical groups for biocrude. The chemical composition of biocrudes is usually determined through gas chromatography-mass spectrometry (GC-MS). However, the vast number of components and high complexity of the biocrude prevent effective chromatographic separation, resulting in broad background signals. More recent studies have used nuclear magnetic resonance (NMR) spectroscopy and Fourier transform ion cyclotron resonance-mass spectrometry (FTICR-MS) to perform analyses with higher resolution and accuracy.

TABLE 15
Groups of chemicals of hydrothermal liquefaction bio-crude

| Main Components | Area % * | Range References |
|---|---|---|
| Phenolics | 6-65 | 1, 2, 5 |
| Esters | 2-44 | 1, 3, 5 |
| Aromatics and heterocyclics | 6-35 | 1, 5 |
| Aldehydes | 0-18 | 1, 2 |
| Carboxylic acids | 2-40 | 2, 3, 4 |
| Ketones | 0-38 | 2, 3, 4, 6 |
| Alkanes | 9-13 | 4, 6 |
| Nitrogenates | 12-23 | 4, 6 |

Note
* Area % from gas chromatography-mass spectrometry results
1 - Rudra, et al.
2 - Ong et al.
3 - Petty et al.
4 - Thigpen, P. L., Final Report: An Investigation of Liquefaction of Wood at the Biomass Liquefaction Facility, Albany, Oregon, Battelle Pacific Northwest Laboratories, Department of Energy, Wheelabrator Cleanfuel Corporation, Technical Information Center, Office of Scientific and Technical Information, U.S. Department of Energy, 1982)
5 - Snowden-Swan et al.
6 - Moura

The effects of varying compositions on the physical properties of diesel and biodiesel have been studied, while for HTL bio-crudes these relationships have not been elucidated. Table 10 shows the properties of various groups in diesel and their effect on fuel properties. In biodiesels, chain length and unsaturation of fatty acids are usually correlated to properties. Increasing chain length increases cetane number (an indication of ignition quality), heating value and viscosity, while increasing unsaturation in fatty acids decreases viscosity and cetane number, but increases density and volumetric heating value. Although these relationships are for diesel and biodiesel, they provide an idea of the potential effects chemical composition may have on the physical properties of HTL biocrude.

TABLE 10
Properties of various chemical groups
and their effect on diesel properties

| Group | Ignition Quality | Heating Value | Density |
|---|---|---|---|
| n-Alkanes | Good | Low | Low |
| Isoalkanes | Low | Low | Low |
| Alkenes | Low | Low | Low |
| Cycloalkanes | Moderate | Moderate | Moderate |
| Aromatics | Poor | High | High |

### Key Fuel Properties

These final fuel properties may not be directly influenced by upgrading processes; however, some consideration should also be given to improving them when processing biocrude. Brief discussions of some key fuel properties to be considered are provided here.

Cetane Number—The Cetane Number (CN) is related to the fuel ignition delay time. Dorn et al. determined the relationship between fuel components and CN. Normal alkanes increase cetane number the most, followed by branched alkanes, normal alkenes, branched alkenes, cycloalkanes, and aromatics. A high CN signifies good ignition quality, good cold start properties, minimal white smoke in exhaust, and low UHC and CO emissions. On the other hand, a low CN is related to a longer ignition delay time, which leads to higher amounts of injected fuel mixed prior to combustion. This then causes high rates of combustion and pressure rise that manifests as diesel knock. This also brings about premixed burning that leads to high combustion temperatures and increased NOx.

Vapor Pressure—Total vapor pressure of the fuel is dependent on the interactions of components within the mixture. Vapor pressure of a mixture can be estimated through the use of activity coefficients and thermodynamic models. These models demonstrate the dependence of vapor pressure on fuel chemical composition. As a fuel property, vapor pressure affects performance of fuels, especially during cold start conditions. However, a high vapor pressure is a concern due to higher fuel evaporation that contributes to increased hydrocarbon emissions.

From the foregoing detailed description of specific embodiments, it should be apparent that patentable systems, methods, and computer-readable media have been described. Although specific embodiments of the disclosure have been described herein in some detail, this has been done solely for the purposes of describing various features and aspects of the systems, methods and media, and is not intended to be limiting with respect to the scope of the systems, methods and media. It is contemplated that various substitutions, alterations, and/or modifications, including but not limited to those implementation variations which may have been suggested herein, may be made to the described embodiments without departing from the scope of the appended claims.

What is claimed is:

1. A method of modeling of a hydrothermal system, the methods comprising:
a) selecting flow rate, physical properties, and chemical properties of a biomass slurry precursor composition and one or more chemical additives to be mixed therewith;
b) selecting operating parameters of solids attrition and mixing equipment;
c) modeling formation of a biomass slurry using data input from steps (a) and (b);
d) modeling a well reactor and hydrothermal reactions, the well reactor comprising:
1) one or more tubing positioned inside a casing of a well in a subterranean formation, the well having a well depth, a well top positioned at a surface location, and a bottom portion positioned at a subterranean location, the casing and the one or more tubing positioned therein forming an annulus there between;
2) the casing and the one or more tubing defining an HTL or HTC reaction zone in the bottom portion of the well and a heat transfer and separation zone above the HTL or HTC reaction zone;
3) one or more cables each comprising an electric heating element positioned in respective one or more of the one or more tubing, the heating element positioned in the HTL or HTC reaction zone;
e) modeling the biomass slurry continuously flowing into the top of the well at a first temperature and a first pressure, and flowing downward through at least one of the one or more tubing, to form a continuously flowing biomass slurry stream;
f) modeling heating of the continuously flowing biomass slurry stream in the HTL or HTC reaction zone employing the electrical heating element;
g) modeling a multiphase, continuously flowing product fluid stream in the HTL or HTC reaction zone, the well depth and the electrical heating element configured to produce a second temperature and a second pressure in the HTL or HTC reaction zone sufficient to form sub-critical water but insufficient to form supercritical water, the multiphase, continuously flowing fluid product stream flowing upward through the annulus and thermally interacting with the continuously flowing biomass slurry stream flowing downward through the one or more tubing;
h) modeling heat transfer between the multiphase, continuously flowing product fluid stream, the well, and the formation, and optionally through the casing and casing construction materials, using a first equation;
i) modeling heat transfer between the multiphase, continuously flowing product fluid stream and the continuously flowing biomass slurry using a second equation;
j) modeling heat transfer between the heating element and the continuously flowing biomass slurry using a third equation, wherein the first equation, the second equation, and the third equation form a coupled system of equations; and
k) performing a mass and energy balance for the well reactor and the subterranean formation by solving the coupled system of equations numerically, providing heat transfer rates to determine the pressure, temperature and quality profile in the continuously flowing product fluid stream.

2. The method of claim 1 comprising modeling frictional pressure losses for one or more of the continuously flowing streams.

3. The method of claim 1 comprising factoring in a gravitational gradient based on in-situ density of one or more of the streams calculated using a Pressure-Volume-Temperature model.

4. The method of claim 1 comprising:
modeling and performing a mass and energy balance for a surface separation system and performing an overall mass and energy balance for the well reactor, the subterranean formation, and the surface separation system.

5. The method of claim 1 comprising a computer server and software in or accessible to the computer server, the computer server using said software to implement the method to aid in thermal-hydraulic analysis of different prospects and well designs.

6. The method of claim 5 wherein the software models systems producing fluids selected from the group consisting of water, hydrocarbons, and mixtures thereof.

7. The method of claim 1 comprising modeling the continuous flowing biomass slurry and the continuous flowing product fluid in a substantially parallel counterflow arrangement.

8. The method of claim 4 wherein the HTL or HTC reaction zone is an HTL reaction zone, comprising modeling:
a) separating the multiphase, continuous flowing product fluid into a liquid stream comprising water and raw biocrude oil, solids comprising biochar, and gaseous products;
b) separating the liquid stream into the water and the raw biocrude oil; and
c) treating the raw biocrude oil to produce a polished biocrude oil suitable for sale.

10. The method of claim 1 comprising modeling delivering the continuously flowing biomass slurry into the one or more tubing at the top of the well to generate enough hydraulic energy to force the multiphase, continuously flowing product fluid to exit the annulus to be routed to a surface separation system without submersible pumping, allowing continuous circulating flow of the continuously flowing biomass slurry into the well and flow of the multiphase, continuously flowing product fluid out of the well using only hydrostatic head.

11. The method of claim 1 wherein the HTL or HTC reaction zone is an HTL reaction zone and the modeling of heat transfer between the continuously flowing biomass slurry flowing downward through the one or more tubing and the multiphase, continuously flowing product fluid traversing upward through the annulus comprises:
a) modeling position and length of the heat transfer and separation zone, and
b) modeling transition of the continuously flowing product fluid from a substantially liquid product to a substantially oil mist product as the continuously flowing product fluid flows out of the well.

12. The method of claim 1 wherein the HTL or HTC reaction zone is an HTL reaction zone, and the method further comprises modeling hydrothermal liquefaction (HTL) in the HTL reaction zone.

13. The method of claim 1 wherein the HTL or HTC reaction zone is an HTC reaction zone, and the method further comprises modeling hydrothermal carbonization (HTC) in the HTC reaction zone.

14. The method of claim 1 wherein the modeling comprises assigning a flow rate, temperature, and pressure of the continuously flowing biomass slurry, and a tubing hydraulic diameter, to model turbulent flow conditions of the continuously flowing biomass slurry through the one or more tubing in the HTL or HTC reaction zone.

15. The method of claim 12 wherein the modeling comprises assigning a Reynolds Number to the continuously flowing biomass slurry flowing through the one or more tubing in the HTL reaction zone sufficient to reduce residence time sufficient to disfavor carbonization of the continuously flowing biomass slurry and favor hydrothermal liquefaction of the continuously flowing biomass slurry to form the biocrude oil.

16. The method of claim 1 comprising assigning values to the well depth, a tubing hydraulic diameter, and the electrical heating element sufficient to control temperature of the continuously flowing biomass slurry to a temperature:
a) ranging from about 200° C. to about 370° C. to favor HTL of the continuously flowing biomass slurry and disfavor carbonization and hydrothermal gasification of the continuously flowing biomass slurry; or
b) ranging from about 180° C. to about 250° C. under autogenous (automatically generated) pressure to favor HTC of the continuously flowing biomass slurry.

17. The method of claim 1 comprising modeling shear-thinning of a biomass slurry precursor composition with one or more non-thermally sensitive inorganic additives to form the continuously flowing biomass slurry.

18. The method of claim 1 wherein the HTL or HTC reaction zone is an HTL reaction zone, the method further comprising providing the well with a well depth of at least 2000 meters (at least 6,600 feet) and positioning the heat transfer and separation zone at a length ranging from about 1000 meters to just under 2000 meters.

19. A computer-readable medium encoded with non-transitory processing instructions for implementing a method, the method comprising:
a) selecting flow rate, physical properties, and chemical properties of a biomass slurry precursor composition and one or more chemical additives to be mixed therewith;
b) selecting operating parameters of solids attrition and mixing equipment;
c) modeling formation of a biomass slurry using data input from steps (a) and (b);
d) modeling a well reactor and hydrothermal reactions, the well reactor comprising:
1) one or more tubing positioned inside a casing of a well in a subterranean formation, the well having a well depth, a well top positioned at a surface location, and a bottom portion positioned at a subterranean location, the casing and the one or more tubing positioned therein forming an annulus there between;
2) the casing and the one or more tubing defining an HTL or HTC reaction zone in the bottom portion of the well and a heat transfer and separation zone above the HTL or HTC reaction zone;
3) one or more cables each comprising an electric heating element positioned in respective one or more of the one or more tubing, the heating element positioned in the HTL or HTC reaction zone;
e) modeling the biomass slurry continuously flowing into the top of the well at a first temperature and a first pressure, and flowing downward through at least one of the one or more tubing, to form a continuously flowing biomass slurry stream;
f) modeling heating of the continuously flowing biomass slurry stream in the HTL or HTC reaction zone employing the electrical heating element;
g) modeling a multiphase, continuously flowing product fluid stream in the HTL or HTC reaction zone, the well depth and the electrical heating element configured to produce a second temperature and a second pressure in the HTL or HTC reaction zone sufficient to form sub-critical water but insufficient to form supercritical water, the multiphase, continuously flowing product fluid stream flowing upward through the annulus and thermally interacting with the continuously flowing biomass slurry stream flowing downward through the one or more tubing;
h) modeling heat transfer between the multiphase, continuously flowing product fluid stream, the well, and the formation, and optionally through the casing and casing construction materials, using a first equation;
i) modeling heat transfer between the multiphase, continuously flowing product fluid stream and the continuously flowing biomass slurry using a second equation;
j) modeling heat transfer between the heating element and the continuously flowing biomass slurry using a third equation, wherein the first equation, the second equation, and the third equation form a coupled system of equations; and
k) performing a mass and energy balance for the well reactor and the subterranean formation by solving the coupled system of equations numerically, providing heat transfer rates to determine the pressure, temperature and quality profile in the continuously flowing product fluid stream.

20. A method of modeling of a hydrothermal system, the method comprising:
a) selecting a geothermal temperature model of a formation as a function of depth;
b) selecting lithology and thermal conductivity of the formation;
c) selecting a wellbore construction 3D geometric model, the wellbore construction 3D model comprising:
1) one or more tubing positioned inside a casing in a subterranean formation, a well depth, a well top positioned at a surface location, and a bottom portion positioned at a subterranean location, the casing and the one or more tubing positioned therein forming an annulus there between;
2) the casing and the one or more tubing defining an HTL or HTC reaction zone in the bottom portion of the well and a heat transfer and separation zone above the HTL or HTC reaction zone; and
3) one or more cables each comprising an electric heating element positioned in respective one or more of the one or more tubing, the heating element positioned in the HTL or HTC reaction zone;
d) forming a formation subsurface segmentation profile using steps (a)-(c) and calculating an overall heat transfer coefficient between the wellbore construction 3D model and the formation;
e) selecting boundary conditions at a casing/formation interface;
f) inputting biomass slurry composition and heat input from an electrical heating element positioned in the HTL or HTC reaction zone in the wellbore to produce a value of total heat that would be generated in the wellbore from hydrothermal reactions in the wellbore;
g) modeling a steady state conduction heat flow at the casing/formation interface using the overall heat transfer coefficient, the boundary conditions, and the value of total heat generated in the wellbore from the hydrothermal reactions in the wellbore; and
h) modeling at least one of:
1) a formation 3D temperature distribution model at a time t;
2) a formation 3D heat loss rate at a distance d from the wellbore; and
3) a formation heat flux at the time t and the distance d.

21. The method of claim 20 comprising using the modeling of the formation heat flux at the time t and the distance d to model transient heat transfer from the wellbore to the formation.

22. The method of claim 21 comprising a) calculating heat loss to the formation at a time t0, a distance d0, and a formation temperature T₀;
b) selecting a time tₓ and a distance dₓ, and calculating heat flux and formation temperature Tₓ at time tₓ and distance dₓ;
c) calculating a formation temperature Tx+1 at a time tx+1 and a distance dx+1 using the formation temperature Tx and calculated heat flux at time tₓ and distance dₓ;
d) comparing Tₓ with Tₓ₊₁, and if not equal, return to step (b), and if equal use Tₓ₊₁ to calculate total heat loss to the formation over time tₓ₊₁;
e) if the value of total heat that would be generated in the wellbore from hydrothermal reactions in the wellbore is greater than the total heat loss to the formation over time, initiating a simulated biomass slurry pumping into the one or more tubing of the wellbore construction 3D geometric model; and
f) if the value of total heat that would be generated in the wellbore from hydrothermal reactions in the wellbore is less than the total heat loss to the formation over time, continue heating the wellbore construction 3D geometric model.

23. A computer-readable medium encoded with non-transitory processing instructions for implementing a method, the method comprising:
a) selecting a geothermal temperature model of a formation as a function of depth;
b) selecting lithology and thermal conductivity of the formation;
c) selecting a wellbore construction 3D geometric model, the wellbore construction 3D model comprising:
1) one or more tubing positioned inside a casing in a subterranean formation, a well depth, a well top positioned at a surface location, and a bottom portion positioned at a subterranean location, the casing and the one or more tubing positioned therein forming an annulus there between;
2) the casing and the one or more tubing defining an HTL or HTC reaction zone in the bottom portion of the well and a heat transfer and separation zone above the HTL or HTC reaction zone; and
3) one or more cables each comprising an electric heating element positioned in respective one or more of the one or more tubing, the heating element positioned in the HTL or HTC reaction zone;
d) forming a formation subsurface segmentation profile using steps (a)-(c) and calculating an overall heat transfer coefficient between the wellbore construction 3D model and the formation;
e) selecting boundary conditions at a casing/formation interface;
f) inputting biomass slurry composition and heat input from an electrical heating element positioned in the HTL or HTC reaction zone in the wellbore to produce a value of total heat that would be generated in the wellbore from hydrothermal reactions in the wellbore;
g) modeling a steady state conduction heat flow at the casing/formation interface using the overall heat transfer coefficient, the boundary conditions, and the value of total heat generated in the wellbore from the hydrothermal reactions in the wellbore; and
h) modeling at least one of:
1) a formation 3D temperature distribution model at a time t;
2) a formation 3D heat loss rate at a distance d from the wellbore; and
3) a formation heat flux at the time t and the distance d.

24. The computer-readable medium of claim 23 wherein the method comprises using the modeling of the formation heat flux at the time t and the distance d to model transient heat transfer from the wellbore to the formation.

25. The computer-readable medium of claim 24 wherein the method comprises
a) calculating heat loss to the formation at a time t0, a distance d0, and a formation temperature T₀;
b) selecting a time tₓ and a distance dₓ, and calculating heat flux and formation temperature Tₓ at time tₓ and distance dₓ;
c) calculating a formation temperature Tx+1 at a time tx+1 and a distance dx+1 using the formation temperature Tx and calculated heat flux at time tₓ and distance dₓ;
d) comparing Tₓ with T_{x+1,} and if not equal, return to step (b), and if equal use Tₓ₊₁ to calculate total heat loss to the formation over time tₓ₊₁;
e) if the value of total heat that would be generated in the wellbore from hydrothermal reactions in the wellbore is greater than the total heat loss to the formation over time, initiating a simulated biomass slurry pumping into the one or more tubing of the wellbore construction 3D geometric model; and
f) if the value of total heat that would be generated in the wellbore from hydrothermal reactions in the wellbore is less than the total heat loss to the formation over time, continue heating the wellbore construction 3D geometric model.
